(19) United States
(12) Patent Application Publication
(10) Pub. No.: US 2008/0296653 A1
(43) Pub. Date: Dec. 4, 2008

(54) Semiconductor memory

(76) Inventors: Yoshio Ozawa, Yokohama-shi (JP); Katsuaki Natori, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/889,679

(22) Filed: Aug. 15, 2007

(30) Foreign Application Priority Data
Aug. 17, 2006 (JP) 2006-222416

(51) Int. Cl. H01L 27/115

(52) U.S. Cl. 257/316; 257/E27.103

(57) ABSTRACT

A semiconductor memory device of an aspect of the present invention comprises a plurality of memory cell transistors arranged in a memory cell array, a select transistor which is disposed in the memory cell array and which selects the memory cell transistor, and a peripheral circuit transistor provided in a peripheral circuit which controls the memory cell array, the memory cell transistor including a gate insulating film provided on a semiconductor substrate, a floating gate electrode provided on the gate insulating film, a between-storage-layer-and-electrode insulating film which is provided on the floating gate electrode and through which the amount of passing charge is greater than that through the gate insulating film during the application of an electric field in write and erase operations of the semiconductor memory, and a control gate electrode on the between-storage-layer-and-electrode insulating film.

### CROSS-REFERENCE TO RELATED APPLICATIONS

This application is based upon and claims the benefit of priority from prior Japanese Patent Application No. 2006-222416, filed Aug. 17, 2006, the entire contents of which are incorporated herein by reference.

### BACKGROUND OF THE INVENTION

1. Field of the Invention

The present invention relates to a semiconductor memory, and more particularly, it relates to a semiconductor memory comprising a memory cell transistor with a gate electrode structure in which a between-storage-layer-and-electrode insulating film is interposed between a charge storage layer and a control gate electrode.

2. Description of the Related Art

A transistor of a memory cell array and a peripheral circuit in a nonvolatile semiconductor memory has a channel region interposed between diffusion layers in an element formation region surrounded by an isolation insulating film on the surface of a semiconductor substrate. A floating gate electrode as a charge storage layer is provided on the channel region of a memory cell transistor of the memory cell array via a gate insulating film (tunnel insulating film). Further, a control gate electrode is provided on the floating gate electrode via a between-storage-layer-and-electrode insulating film. Then, the entire memory cell transistor is covered with an interlayer insulating film.

In contrast, a gate electrode is provided on the channel region of the transistor of the peripheral circuit (hereinafter referred to as “peripheral circuit transistor”). Then, the entire peripheral circuit transistor is covered with an interlayer insulating film.

Furthermore, a select transistor of the memory cell array which selects the memory cell transistor has the same configuration as that of the peripheral circuit transistor.

In the manufacture of the nonvolatile semiconductor memory, the gate insulating film (tunnel insulating film) of the memory cell transistor and the gate insulating film of the peripheral circuit transistor are formed in the same process in order to simplify the manufacturing process and reduce manufacturing costs. Moreover, the gate electrode of the peripheral circuit transistor is formed by electrically connecting two conductive layers used as the floating gate electrode and the control gate electrode of the memory cell transistor.

In general, write and erase operations of the nonvolatile semiconductor memory are achieved by the application of a voltage across the control gate electrode of the memory cell transistor and the semiconductor substrate. In other words, a charge is transferred between the channel region in the semiconductor substrate and the floating gate electrode via the gate insulating film (tunnel insulating film) to vary the threshold value of the memory cell transistor such that the write and erase operations are achieved.

In the nonvolatile semiconductor memory, a charge with high energy passes in great quantities through the tunnel insulating film during the write and erase operations. Thus, a charge trap level is formed in the tunnel insulating film such that the charge is trapped or a leakage current is generated, resulting in the deterioration in quality of the tunnel insulating film of the nonvolatile semiconductor memory.

Therefore, the repetition of the write and erase operations decreases the insulating properties of the tunnel insulating film and makes it difficult to attain the maintenance of the charge in the floating gate electrode which is an important function of the nonvolatile semiconductor memory.

In order to avoid the problem of the deterioration in quality of the tunnel insulating film, the thickness of the tunnel insulating film comprising a silicon oxide (SiO₂) or a silicon oxynitride (SiON) film is typically set high at 8 nm or more. As a result, the thickness of the gate insulating film of the peripheral circuit transistor is also large, so that there has been a problem of the decrease in the operation speed of the peripheral circuit.

Furthermore, the operating voltage of the memory cell array of the nonvolatile semiconductor memory is high at about 20V, so that there have been problems of decreased withstand voltage, increased power consumption, etc.

These problems become more evident as the nonvolatile semiconductor memory is more miniaturized, and are particularly serious when a channel length or channel width is less than 100 nm. Similar problems are also found in a nonvolatile semiconductor memory using a memory cell transistor with a so-called metal-oxide-nitride-oxide-semiconductor (MONOS) structure in which a charge storage layer is made of an insulating film.

In order to solve the above-mentioned problems, there has been proposed a memory such as a scalable two transistor memory device which transfers a charge between a control gate electrode and a floating gate electrode to achieve the write and erase operations (e.g., refer to the specification of U.S. Pat. No. 6,475,857B1.).

However, the above-mentioned device which transfers a charge between the control gate electrode and the floating gate electrode requires another gate electrode for controlling the transfer of the charge between the control gate electrode and the floating gate electrode.

Therefore, its manufacturing process is complicated. Another problem is that it is not suited to high-speed operation due to the parasitic capacitance between the newly added gate electrode and the control gate electrode.

### BRIEF SUMMARY OF THE INVENTION

A semiconductor memory device of an aspect of the present invention comprises: a plurality of memory cell transistors arranged in a memory cell array; a select transistor which is disposed in the memory cell array and which selects the memory cell transistor; and a peripheral circuit transistor provided in a peripheral circuit which controls the memory cell array, the memory cell transistor including: a gate insulating film provided on a semiconductor substrate; a floating gate electrode as a charge storage layer provided on the gate insulating film; a between-storage-layer-and-electrode insulating film which is provided on the floating gate electrode and through which the amount of passing charge is greater than that through the gate insulating film during the application of an electric field in write and erase operations of the semiconductor memory; and a control gate electrode on the between-storage-layer-and-electrode insulating film.

A semiconductor memory device of an aspect of the present invention comprises: a plurality of memory cell transistors arranged in a memory cell array; a select transistor which is disposed in the memory cell array and which selects the memory cell transistor; and a peripheral circuit transistor provided in a peripheral circuit which controls the memory cell array, the memory cell transistor including: a gate insulating film provided on a semiconductor substrate; an insulating film as a charge storage layer provided on the gate insulating film; a between-storage-layer-and-electrode insulating film which is provided on the insulating film as the charge storage layer and through which the amount of passing charge is greater than that through the gate insulating film during the application of an electric field in write and erase operations of the semiconductor memory; and a control gate electrode on the between-storage-layer-and-electrode insulating film.

### BRIEF DESCRIPTION OF THE SEVERAL VIEWS OF THE DRAWING

FIG. 1 is an equivalent circuit diagram of a semiconductor memory according to a first embodiment;

FIG. 2 is a diagram showing the layout pattern of part of a memory cell array shown in FIG. 2;

FIG. 3 is a sectional view of a memory cell transistor sectioned in a bit line direction;

FIG. 4 is a sectional view of a peripheral circuit transistor sectioned in the bit line direction;

FIG. 5 is a graph showing an example of the electric conduction characteristics of a between-storage-layer-and-electrode insulating film of the memory cell transistor in the semiconductor memory according to the first embodiment;

FIG. 6 is an energy band diagram for explaining the electric conduction characteristics of the between-storage-layer-and-electrode insulating film of the memory cell transistor in the first embodiment;

FIG. 7 is an energy band diagram for explaining the electric conduction characteristics of the between-storage-layer-and-electrode insulating film of the memory cell transistor in the first embodiment;

FIG. 8 is an energy band diagram for explaining the electric conduction characteristics of the between-storage-layer-and-electrode insulating film of the memory cell transistor in the first embodiment;

FIG. 9 is an energy band diagram for explaining the electric conduction characteristics of the storage layer-electrode insulating film of the memory cell transistor in the first embodiment;

FIG. 10 is an energy band diagram for explaining the electric conduction characteristics of the between-storage-layer-and-electrode insulating film of the memory cell transistor in the first embodiment;

FIG. 11 is a sectional view for explaining a semiconductor memory manufacturing method according to the first embodiment;

FIG. 12 is a process sectional view for explaining the semiconductor memory manufacturing method according to the first embodiment;

FIG. 13 is a process sectional view for explaining the semiconductor memory manufacturing method according to the first embodiment;

FIG. 14 is a process sectional view for explaining the semiconductor memory manufacturing method according to the first embodiment;

FIG. 15 is a process sectional view for explaining the semiconductor memory manufacturing method according to the first embodiment;

FIG. 16 is a process sectional view for explaining the semiconductor memory manufacturing method according to the first embodiment;

FIG. 17 is a process sectional view for explaining the semiconductor memory manufacturing method according to the first embodiment;

FIG. 18 is a process sectional view for explaining the semiconductor memory manufacturing method according to the first embodiment;

FIG. 19 is a process sectional view for explaining the semiconductor memory manufacturing method according to the first embodiment;

FIG. 20 is a process sectional view for explaining the semiconductor memory manufacturing method according to the first embodiment;

FIG. 21 is a process sectional view for explaining the semiconductor memory manufacturing method according to the first embodiment;

FIG. 22 is a process sectional view for explaining the semiconductor memory manufacturing method according to the first embodiment;

FIG. 23 is a process sectional view for explaining the semiconductor memory manufacturing method according to the first embodiment;

FIG. 24 is a process sectional view for explaining the semiconductor memory manufacturing method according to the first embodiment;

FIG. 25 is a process sectional view for explaining the semiconductor memory manufacturing method according to the first embodiment;

FIG. 26 is a process sectional view for explaining the semiconductor memory manufacturing method according to the first embodiment;

FIG. 27 is a process sectional view for explaining the semiconductor memory manufacturing method according to the first embodiment;

FIG. 28 is a process sectional view for explaining the semiconductor memory manufacturing method according to the first embodiment;

FIG. 29 is a sectional view of a memory cell transistor of a semiconductor memory according to a first modification of the first embodiment;

FIG. 30 is a sectional view of the memory cell transistor of the semiconductor memory according to the first modification of the first embodiment;

FIG. 31 is a sectional view of a memory cell transistor of a semiconductor memory according to a second modification of the first embodiment;

FIG. 32 is a sectional view of the memory cell transistor of the semiconductor memory according to the second modification of the first embodiment;

FIG. 33 is a sectional view of a memory cell transistor of a semiconductor memory according to a second embodiment;

FIG. 34 is a sectional view of the memory cell transistor of the semiconductor memory according to the second embodiment;

FIG. 35 is a sectional view for explaining a semiconductor memory manufacturing method according to the second embodiment;

FIG. 36 is a sectional view for explaining the semiconductor memory manufacturing method according to the second embodiment;

FIG. 37 is a sectional view for explaining the semiconductor memory manufacturing method according to the second embodiment;

FIG. 38 is a sectional view for explaining the semiconductor memory manufacturing method according to the second embodiment;

FIG. 39 is a sectional view for explaining the semiconductor memory manufacturing method according to the second embodiment;

FIG. 40 is a sectional view for explaining the semiconductor memory manufacturing method according to the second embodiment;

FIG. 41 is a sectional view for explaining the semiconductor memory manufacturing method according to the second embodiment;

FIG. 42 is a sectional view for explaining the semiconductor memory manufacturing method according to the second embodiment;

FIG. 43 is a sectional view for explaining the semiconductor memory manufacturing method according to the second embodiment;

FIG. 44 is a sectional view of the memory cell transistor of the semiconductor memory according to a modification of the second embodiment;

FIG. 45 is a sectional view of the memory cell transistor of the semiconductor memory according to the modification of the second embodiment;

FIG. 46 is a sectional view of a memory cell transistor of a semiconductor memory according to a third embodiment;

FIG. 47 is a sectional view of the memory cell transistor of the semiconductor memory according to the third embodiment;

FIG. 48 is a sectional view for explaining a semiconductor memory manufacturing method according to the third embodiment;

FIG. 49 is a sectional view for explaining the semiconductor memory manufacturing method according to the third embodiment;

FIG. 50 is a sectional view for explaining the semiconductor memory manufacturing method according to the third embodiment;

FIG. 51 is a sectional view for explaining the semiconductor memory manufacturing method according to the third embodiment;

FIG. 52 is a sectional view for explaining the semiconductor memory manufacturing method according to the third embodiment;

FIG. 53 is a sectional view for explaining the semiconductor memory manufacturing method according to the third embodiment;

FIG. 54 is a sectional view for explaining the semiconductor memory manufacturing method according to the third embodiment;

FIG. 55 is a sectional view for explaining the semiconductor memory manufacturing method according to the third embodiment;

FIG. 56 is a sectional view for explaining the semiconductor memory manufacturing method according to the third embodiment;

FIG. 57 is a sectional view for explaining the semiconductor memory manufacturing method according to the third embodiment;

FIG. 58 is a sectional view for explaining the semiconductor memory manufacturing method according to the third embodiment;

FIG. 59 is a sectional view for explaining the semiconductor memory manufacturing method according to the third embodiment;

FIG. 60 is a sectional view for explaining the semiconductor memory manufacturing method according to the third embodiment;

FIG. 61 is a sectional view for explaining the semiconductor memory manufacturing method according to the third embodiment; and

FIG. 62 is a sectional view for explaining the semiconductor memory manufacturing method according to the third embodiment.

### DETAILED DESCRIPTION OF THE INVENTION

Next, first to third embodiments of the present invention will be described with reference to the drawings. In the following description of the drawings, the same or similar numbers are assigned to the same or similar parts. However, it is to be noted that the drawings are schematic and the relation between the thickness and planar dimensions, the ratio of the thicknesses of layers, etc., are different from real ones. Therefore, specific thickness and dimensions should be judged in consideration of the following description. It should also be understood that parts different from each other in dimensions and ratios are contained in the drawings.

The first to third embodiments shown below illustrate a device and method for embodying the technical idea of this invention, and the technical idea of this invention does not limit the materials, shapes, structures, arrangements, etc., of components to those described below. Various modifications can be made in the technical idea of this invention in claims.

### First Embodiment

<Structure>

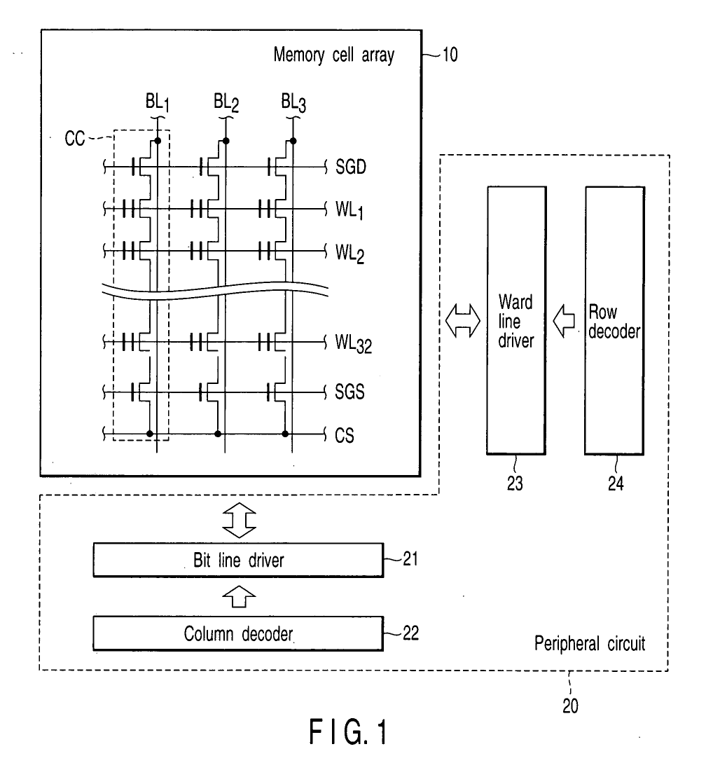

FIGS. 1 to 4 show a semiconductor memory according to a first embodiment of the present invention. As shown in FIG. 1, a memory cell array 10 comprises a plurality of memory cell columns CC arranged in a row direction in which a plurality of memory cell transistors and select transistors for selecting the memory cell transistors are arranged in a column direction.

Furthermore, a peripheral circuit 20 is provided on the periphery of the memory cell array 10 to control the memory cell array 10.

That is, the semiconductor memory according to the first embodiment of the present invention comprises the memory cell array 10 having a plurality of bit lines BL₁, BL₂, BL₃, . . . , arranged in the column direction and a plurality of word lines WL₁, WL₂, WL₃, . . . , arranged in the row direction perpendicular to bit lines BL₁, BL₂, BL₃, . . . . Further, in the memory cell array 10, the memory cell transistors whose charge storage states are controlled by any one of word lines WL₁, WL₂, WL₃, . . . , are arranged in the column direction in FIG. 1.

FIG. 1 shows a case where 32 memory cell transistors are arranged in the column direction to constitute the memory cell column CC. At both ends of the arrangement of the memory cell column CC, there are disposed a pair of select transistors which are disposed adjacently to each other in the column direction and which select a group of memory cell transistors arranged in the memory cell column CC. A pair of selection gate interconnects SGD, SGS is connected to the gate of each of the pair of select transistors.

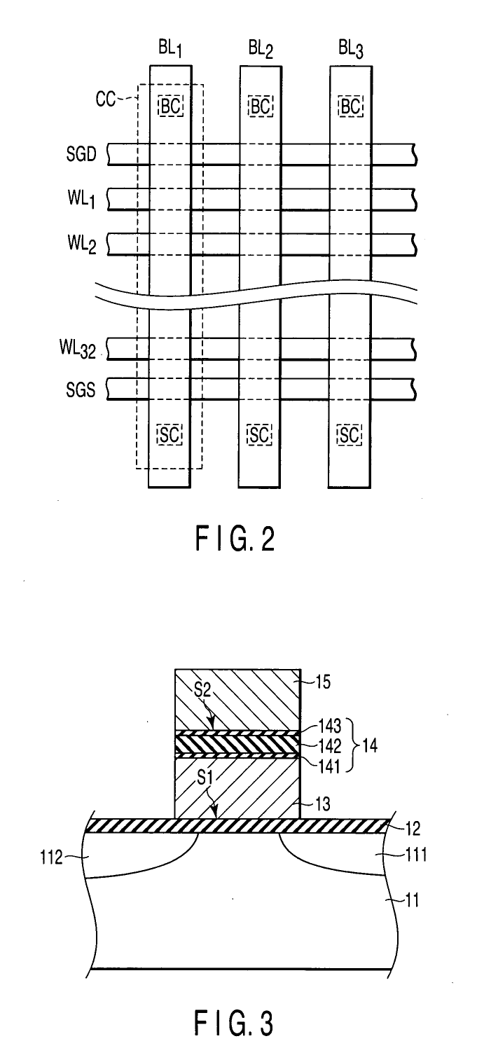

FIG. 2 is a diagram of a layout pattern configuration corresponding to an equivalent circuit of the memory cell array 10 shown in FIG. 1. As shown in FIG. 2, the drain terminals of the bit line side select transistors are connected to bit lines BL₁, BL₂, BL₃, . . . , via vias BC. The source terminals of the source line side select transistors are connected to a cell source line CS shown in FIG. 1 via vias SC.

Furthermore, the peripheral circuit 20 of the semiconductor memory shown in FIG. 1 includes a bit line driver 21, a column decoder 22, a word line driver 23 and a row decoder 24. The bit line driver 21 is connected to bit lines BL₁, BL₂, BL₃, . . . , of the memory cell array 10. The word line driver 23 is connected to word lines WL₁, WL₂, WL₃, . . . , of the memory cell array 10. The column decoder 22 is connected to the bit line driver 21, and the row decoder 24 is connected to the word line driver 23.

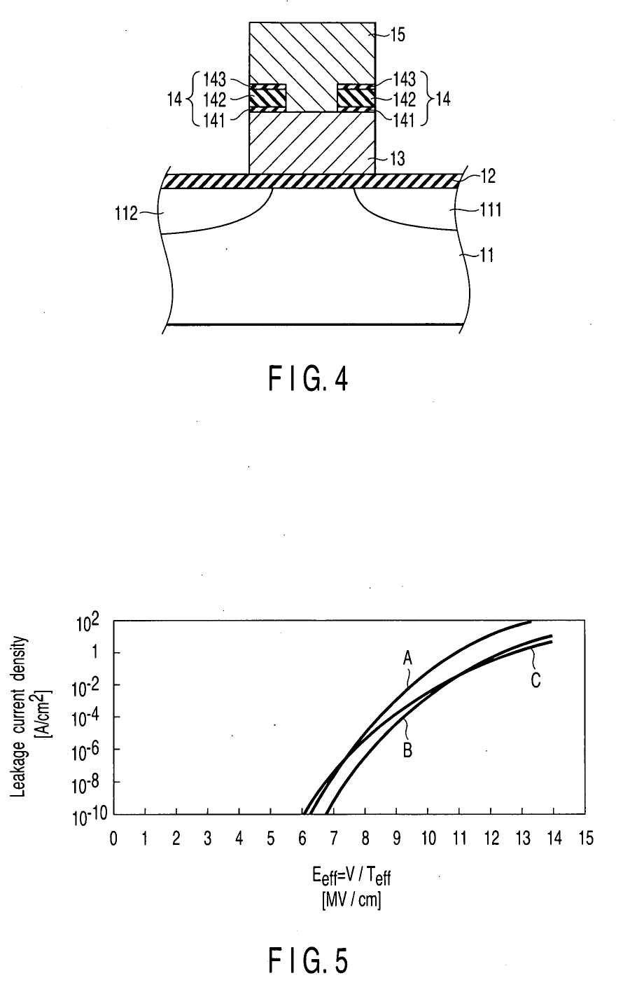

FIGS. 3 and 4 are sectional views of the memory cell transistor and a peripheral circuit transistor provided in the peripheral circuit 20 when viewed in a cross section along the direction of bit lines BL₁, BL₂, BL₃, . . . , shown in FIG. 1.

As shown in FIG. 3, the memory cell transistor provided in the memory cell array 10 of the semiconductor memory according to the first embodiment comprises a gate insulating film 12, a floating gate electrode 13 on the gate insulating film 12, a between-storage-layer-and-electrode insulating film 14 which is disposed on the floating gate electrode 13 as a charge storage layer and through which the amount of a charge passing during the application of an electric field in the write and erase operations of the semiconductor memory is greater than that through the gate insulating film 12, and a control gate electrode 15 on the between-storage-layer-and-electrode insulating film 14. That is, the between-storage-layer-and-electrode insulating film 14 functions as a tunnel insulating film.

Furthermore, a drain region 111 and a source region 112 are disposed across a region where a gate electrode is disposed, in parts of the upper portion of a semiconductor substrate 11. The entire memory cell transistor is covered with an interlayer insulating film (not shown).

Here, “the charge passage amount” is the amount of the charge which passes through an insulating film interposed between conductive layers when an electric field is applied to this insulating film.

The thickness and material of the gate insulating film of the peripheral circuit transistor provided in the peripheral circuit 20 are the same as those of the gate insulating film of the memory cell transistor.

As shown in FIG. 4, the peripheral circuit transistor comprises a gate electrode wherein there are stacked in the following order the gate insulating film 12, a first conductive layer having the same thickness and material as those of the floating gate electrode 13, an insulating film having the same thickness and material as those of the between-storage-layer-and-electrode insulating film 14, and a second conductive layer which is electrically conducted to the first conductive layer through an opening in the insulating film and which has the same thickness and material as those of the control gate electrode 15.

In addition, the surface of the gate electrode in the region of the opening is actually slightly concave when a normal manufacturing method is used, but it is not shown in FIG. 4 for simplicity. Moreover, for clarity of the explanation, the first conductive layer, the second conductive layer and the insulating film between the first conductive layer and the second conductive layer in the peripheral circuit transistor are explained as the floating gate electrode 13, the control gate electrode 15 and the between-storage-layer-and-electrode insulating film 14.

The entire peripheral circuit transistor is covered with an interlayer insulating film (not shown). Moreover, the structure of the select transistor provided in the memory cell array 10 is the same as the structure shown in FIG. 4.

To explain the memory cell transistor in more detail, an area S1 in which the semiconductor substrate 11 faces the floating gate electrode 13 is substantially equal to an area S2 in which the floating gate electrode 13 faces the control gate electrode 15.

Moreover, the gate insulating film 12 provided between the semiconductor substrate 11 and the floating gate electrode 13 is made of a silicon oxide film having a thickness of, for example, 5.4 nm.

Furthermore, the between-storage-layer-and-electrode insulating film 14 provided between the floating gate electrode 13 and the control gate electrode 15 has a structure in which a first insulating film 141, a second insulating film 142 and a third insulating film 143 are stacked. For example, a silicon oxide film having a thickness of 1.3 nm can be employed for the first insulating film 141, an alumina (Al₂O₃) film having a thickness of 8 nm can be employed for the second insulating film 142, and a silicon oxide film having a thickness of 1.3 nm can be employed for the third insulating film 143. In addition, the three stacked films constituting the between-storage-layer-and-electrode insulating film 14 can be formed by depositing the layer films in order starting from the bottom layer film using a method such as the chemical vapor deposition (CVD) method or atomic layer deposition (ALD) method.

The equivalent silicon oxide thickness (hereinafter simply referred to as “equivalent thickness”) Teff of the between-storage-layer-and-electrode insulating film 14 constituted of the three stacked films described above as an example is about 5.4 nm. Here, the equivalent thickness Teff is defined by the thickness of the silicon oxide film indicating a capacitance equal to the capacitance of an insulating film of interest, and equals to a value in which the dielectric constant of the silicon oxide film is divided by capacitance per unit area of the insulating film of interest.

Examples of the electric conduction characteristics of the silicon oxide film and the three stacked films constituted of the silicon oxide film/the alumina film/the silicon oxide film illustrated above are shown in FIG. 5. FIG. 5 shows the results of the measurement of the density of a leakage current running when a voltage is applied to the silicon oxide film or the three stacked films. In FIG. 5, the horizontal axis indicates an equivalent electric field Eeff in which a voltage V applied to the silicon oxide film or the three stacked films is divided by the equivalent thickness Teff, and the vertical axis indicates the leakage current density. In addition, the between-storage-layer-and-electrode insulating film has a vertically symmetrical stacked structure, so that its electric conduction characteristics makes almost no change even if the direction of the applied electric field is changed.

In FIG. 5, a curve A indicates the leakage current density of the three stacked films constituted of the silicon oxide film having a thickness of 1.3 nm, the alumina film having a thickness of 8 nm and the silicon oxide film having a thickness of 1.3 nm. A curve B indicates the leakage current density of the three stacked films constituted of the silicon oxide film having a thickness of 1 nm, the alumina film having a thickness of 9.6 nm and the silicon oxide film having a thickness of 1 nm. A curve C indicates the leakage current density of the silicon oxide film having a thickness of 5.4 nm.

As shown in FIG. 5, the leakage current densities of the three stacked films indicated by curves A and B are higher than the leakage current density of the silicon oxide film indicated by curve C when a high electric field is applied, and lower than the leakage current density of the silicon oxide film when a low electric field is applied.

That is, when the structure of the between-storage-layer-and-electrode insulating film 14 is a three-layer stacked structure in which the alumina film having a higher dielectric constant and a lower potential barrier than those of the silicon oxide film is disposed between the silicon oxide films, the electric conduction efficiency of the between-storage-layer-and-electrode insulating film 14 can be higher than that of the silicon oxide film when a high electric field is applied and can be lower than that of the silicon oxide film when a low electric field is applied. Here, the “electric conduction efficiency” means the easiness of the transfer of a charge via an insulating film interposed by conductive layers when an electric field is applied to this insulating film.

Therefore, a combination of the material of the gate insulating film 12 and the material of the between-storage-layer-and-electrode insulating film 14 is selected so that the electric conduction efficiency of the between-storage-layer-and-electrode insulating film 14 may be higher than that of the gate insulating film 12 in connection with the applied electric field in the write and erase operations.

In this manner, when a high voltage is applied across the semiconductor substrate 11 and the control gate electrode 15, the amount of a charge transferring between the floating gate electrode 13 and the control gate electrode 15 via the between-storage-layer-and-electrode insulating film 14 can be sufficiently greater than the amount of a charge transferring between the channel region in the semiconductor substrate 11 and the floating gate electrode 13 via the gate insulating film 12. That is, the between-storage-layer-and-electrode insulating film 14 can function as a tunnel insulating film.

Specifically, when a voltage of 10V or more is applied across the semiconductor substrate 11 and the control gate electrode 15, voltages of 5V or more are applied to the between-storage-layer-and-electrode insulating film 14 and the gate insulating film 12 by the division of capacitance if the capacitances of the between-storage-layer-and-electrode insulating film 14 and the gate insulating film 12 are substantially the same. At this point, the equivalent electric fields of the between-storage-layer-and-electrode insulating film 14 and the gate insulating film 12 are 9.3 MV/cm or more. Therefore, judging from the electric conduction characteristics shown in FIG. 5, the leakage current density of the between-storage-layer-and-electrode insulating film 14 is more than three times that of the gate insulating film 12. Thus, when one leakage current is about three times the other, it is possible to achieve a high-speed operation enough for a semiconductor memory in which a charge transfers between the control gate electrode 15 and the floating gate electrode 13.

Furthermore, when a voltage of 13V or more is applied across the semiconductor substrate 11 and the control gate electrode 15, voltages of 6.5V or more are applied to the between-storage-layer-and-electrode insulating film 14 and the gate insulating film 12. At this point, the equivalent electric fields of the between-storage-layer-and-electrode insulating film 14 and the gate insulating film 12 are 12 MV/cm or more. Therefore, judging from the electric conduction characteristics shown in FIG. 5, the leakage current density of the between-storage-layer-and-electrode insulating film 14 is more than ten times that of the gate insulating film 12. Thus, when one leakage current is about ten times the other, it is possible to more desirably achieve a high-speed operation enough for a semiconductor memory while avoiding the deterioration in quality of the gate insulating film 12 due to the passage of a high current.

<Electric Conduction Characteristics of Between-Storage-Layer-and-Electrode Insulating Film>

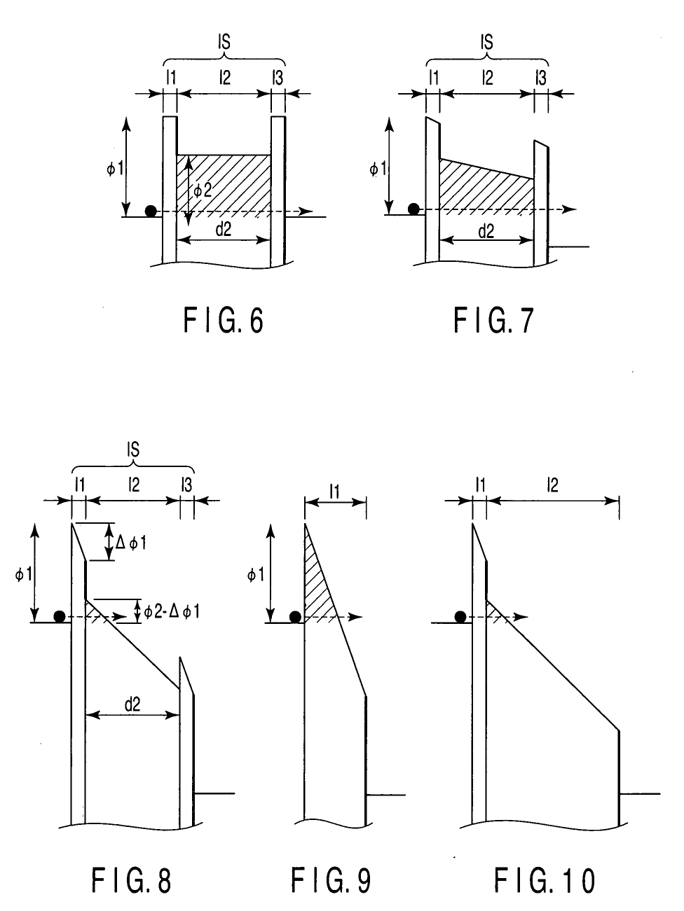

The electric conduction characteristics of the between-storage-layer-and-electrode insulating film 14 are explained below using energy band diagrams shown in FIGS. 6 to 10.

FIG. 6 is an energy band diagram with no application of an electric field regarding an insulating film IS in which an insulating film I2 having a high dielectric constant and a low potential barrier (dielectric constant of ∈2 and potential barrier of φ2) is disposed between insulating films I1 and I3 having a dielectric constant of ∈1 and a potential barrier height of φ1 and which has a stacked structure similar to that of the between-storage-layer-and-electrode insulating film 14 shown in FIG. 3. Here, the relations of the dielectric constants and the heights of the potential barriers are ∈1<∈2 and φ1>φ2.

Most of oxide materials having a dielectric constant higher than that of the silicon oxide film satisfy the above-mentioned relations in which the dielectric constant is higher than that of the silicon oxide film and the height of the potential barrier is lower than that of the silicon oxide film.

When the equivalent thickness Teff of the insulating film IS is constant, the distance of a path through which a charge indicated by a black circle in FIG. 6 is tunnel-conducted in the insulating film IS is the length of a dotted arrow indicated in FIG. 6 because a thickness d2 of the insulating film I2 is large, so that the electric conduction efficiency of the insulating film IS is low.

The potential barrier of the insulating film I2 which is an insulating film portion with a high dielectric constant in the case of no application of an electric field is rectangular, as indicated by hatching in the energy band diagram shown in FIG. 6. The tunnel probability for the rectangular potential barrier is approximately indicated by the product of the square root of the barrier height and the barrier thickness.

Thus, an insulating film material with a high dielectric constant satisfying the relation of Equation (1) below is selected, and the intermediate portion of the insulating film IS which is a single silicon oxide film is replaced with the selected insulating film material with a high dielectric constant, such that the electric conduction efficiency of the insulating film IS is reduced.

(∈2/∈1)×(φ2)^{1/2}<(φ1)^{1/2} (1)

Most of oxide materials having a dielectric constant higher than that of the silicon oxide film satisfy the relation of Equation (1).

FIG. 7 shows an energy band diagram wherein a weak electric field is applied to the insulating film IS constituted of the insulating films I1 to I3. As indicated by hatching in FIG. 7, the potential barrier of the insulating film I2 which is an insulating film portion with a high dielectric constant in the case where the applied electric field is weak is trapezoidal, higher on a charge injection side and lower on a charge output side.

The distance of a path through which a charge indicated by a black circle in FIG. 7 is tunnel-conducted in the insulating film IS is long as indicated by a dotted arrow, so that the distance of the tunnel conduction is long. Therefore, the electric conduction efficiency of the insulating film IS can be reduced when an applied electric field is weak.

FIG. 8 shows an energy band diagram wherein a strong electric field is applied to the insulating film IS constituted of the insulating films I1 to I3. As indicated by hatching in FIG. 8, the potential barrier of the insulating film I2 in the case where the applied electric field is strong is triangular such that the potential barrier reaches zero in the middle of the insulating film I2.

As shown in FIG. 8, the distance of a path through which a charge indicated by a black circle is tunnel-conducted in the insulating film IS is shorter than in the example shown in FIG. 7, as indicated by a solid arrow.

That is, the tunnel conduction distance in the example shown in FIG. 8 is shorter than the tunnel conduction distance in the example shown in FIG. 7. Therefore, the electric conduction efficiency of the insulating film IS in the example shown in FIG. 8 is higher than the electric conduction efficiency of the insulating film IS in the example shown in FIG. 7.

Furthermore, a potential reduction amount ΔΦ1 in the part of the insulating film I1 is large because the insulating film I1 having a dielectric constant lower than that of the insulating film I2 is present on the charge injection side of the insulating film I2. The reason that the potential reduction amount Δφ1 is larger is that an electric field in an insulating film portion with a low dielectric constant corresponding to the inclination of the potential barrier in FIG. 8 is higher than that in the insulating film portion with a high dielectric constant in accordance with Gauss's theorem.

As a result, the substantial height of the potential barrier is reduced to φ2−Δφ1 as shown in FIG. 8, and the electric conduction efficiency of the insulating film IS becomes significantly higher.

For comparison, a case is shown in FIG. 9 of an insulating film having a single layer of the insulating film I1 in which the height of the potential barrier is φ1. The potential barrier shown in FIG. 9 is triangular as indicated by hatching, and the average height of this potential barrier is greater than that of the potential barrier shown in FIG. 8.

In addition, the between-storage-layer-and-electrode insulating film 14 does not necessarily have to be a three-layer stacked film in which the insulating films with a low dielectric constant are disposed on both sides of the insulating film with a high dielectric constant. As shown in the energy band diagram in FIG. 10, if the insulating film I1 whose dielectric constant is lower than that of the insulating film I2 is disposed to contact one side of the insulating film I2, electric conduction characteristics can be achieved whereby the electric conduction efficiency is high during the application of a high electric field and low during the application of a low electric field with regard to the injection of a charge from an electrode located on the side where the insulating film I1 with a low dielectric constant is disposed.

Therefore, when it is desired to only carry out the write operation at high speed, an insulating film with a low dielectric constant has only to be disposed at the interface of the between-storage-layer-and-electrode insulating film 14 on the side of the control gate electrode 15. That is, the between-storage-layer-and-electrode insulating film 14 is composed of the second insulating film 142 and the third insulating film 143.

Moreover, when it is desired to only carry out the erase operation at high speed, an insulating film with a low dielectric constant has only to be disposed at the interface of the between-storage-layer-and-electrode insulating film 14 on the side of the floating gate electrode 13. That is, the between-storage-layer-and-electrode insulating film 14 is composed of the first insulating film 141 and the second insulating film 142.

In addition, exemplary insulating films with a low dielectric constant and high potential barrier include a silicon oxide film, a silicon oxynitride film, a silicon nitride (Si₃N₄) film, etc., and a stack of these films may be used.

Exemplary insulating films with a high dielectric constant and low potential barrier include an alumina film, a tantalum oxide (Ta₂O₅) film, a hafnium oxide (HfO₂) film, a lanthanum oxide (La₂O₃) film, etc. A stack of these films may be used or a mixture including at least one of these insulating film materials may be used. Moreover, other elements such as nitrogen and silicon may be added to the above-mentioned insulating film materials.

That is, for the between-storage-layer-and-electrode insulating film 14, it is possible to employ a stacked structure of any combination of the insulating film material with a low dielectric constant and high potential barrier and the insulating film material with a high dielectric constant and low potential barrier as long as the combination of the insulating materials satisfies ∈1<∈2 and φ1>φ2.

In addition, in order to increase the electric conduction efficiency of the between-storage-layer-and-electrode insulating film 14, the thickness of the insulating film with a low dielectric constant and high potential barrier is desirably set to 0.8 to 2.7 nm in the case of the silicon oxide film, about 1 to 5 nm in the case of the silicon oxynitride film (the equivalent thickness Teff is about 1 to 3 nm), and 2.4 nm or more in the case of the silicon nitride film (the equivalent thickness Teff is 1.2 nm or more).

In particular, the thickness should more desirably be 1.0 to 1.6 nm in the case of the silicon oxide film, where the electric conduction efficiency of the between-storage-layer-and-electrode insulating film 14 improves by about five digits.

As described above, according to the semiconductor memory in the first embodiment, the electric conduction efficiency of the between-storage-layer-and-electrode insulating film 14 significantly improves as compared with the case where the between-storage-layer-and-electrode insulating film is a single layer film with a low dielectric constant, and a charge can be transferred between the control gate electrode 15 and the floating gate electrode 13 via the between-storage-layer-and-electrode insulating film 14 when a voltage is applied across the semiconductor substrate 11 and the control gate electrode 15.

It should be understood that the material with a low dielectric constant for the between-storage-layer-and-electrode insulating film 14 and the material of the gate insulating film 12 may be the same but they may also be different. It is only necessary that the leakage current density of the between-storage-layer-and-electrode insulating film 14 be, for example, three times the leakage current density of the gate insulating film 12. Moreover, although the case has been shown where the equivalent thicknesses Teff of the gate insulating film 12 and the between-storage-layer-and-electrode insulating film 14 are constant, it should be understood that the present invention is not limited to the case where the equivalent thickness Teff is constant.

In addition, it should be noted that when the equivalent thicknesses Teff of the gate insulating film 12 and the between-storage-layer-and-electrode insulating film 14 are different from each other, the ratio of voltages applied to the gate insulating film 12 and the between-storage-layer-and-electrode insulating film 14 by the division of capacitance is Teff1:Teff2 where Teff1 is the equivalent thickness of the gate insulating film 12 and Teff2 is the equivalent thickness of the between-storage-layer-and-electrode insulating film 14.

That is, a charge can be transferred between the control gate electrode 15 and the floating gate electrode 13 via the between-storage-layer-and-electrode insulating film 14 if the equivalent thicknesses Teff1, Teff2 and an electric field applied during the write and erase operations are set so that the electric conduction efficiency of the between-storage-layer-and-electrode insulating film 14 in the case of an electric field multiplied by (Teff1/Teff2) is higher than the electric conduction efficiency of the gate insulating film 12 in the case of a certain electric field.

A convex curved surface can be provided in an interface on the upper side of the floating gate electrode 13 or in an interface on the lower side of the control gate electrode 15 to increase the electric field on the charge injection side of the between-storage-layer-and-electrode insulating film 14 and increase the electric conduction efficiency of the between-storage-layer-and-electrode insulating film 14.

That is, the amount of the charge passing through the between-storage-layer-and-electrode insulating film 14 can be greater than the amount of the charge passing through the gate insulating film 12. For example, when the conductive layer has a convex curved surface in the section in one of the channel length direction or a channel width direction, the ratio R/Teff of the equivalent thickness Teff of the between-storage-layer-and-electrode insulating film 14 to the curvature R of the convex curved surface should desirably be 2 or less. When the ratio R/Teff is 2 or less, the electric field in the vicinity of the charge injection side interface increases by 20% or more, and the efficiency of charge injection increases more than 100 times.

Moreover, the ratio R/Teff should desirably be 1 or less. When the ratio R/Teff is 1 or less, the electric field in the vicinity of the charge injection side interface increases by 40% or more, and the efficiency of charge injection increases more than 10000 times. Further, if the conductive layer has convex curved surfaces in both the sections in the channel length direction and the channel width direction, the efficiency of charge injection desirably increases more.

A condition is described below where a charge is transferred between the control gate electrode 15 and the floating gate electrode 13 via the between-storage-layer-and-electrode insulating film 14 when a voltage is applied across the semiconductor substrate 11 and the control gate electrode 15.

When a voltage Vcg is applied across the semiconductor substrate 11 and the control gate electrode 15, the applied voltage Vcg is divided and applied to the gate insulating film 12 and the between-storage-layer-and-electrode insulating film 14. That is, Vcg=V1+V2 where V1 is the voltage applied to the gate insulating film 12 and V2 is the voltage applied to the between-storage-layer-and-electrode insulating film 14.

A voltage division factor β at this point is defined as β=V2/Vcg. That is, the voltage division factor β is the proportion of a voltage which is applied to the between-storage-layer-and-electrode insulating film 14 and which contributes to the transfer of the charge between the control gate electrode 15 and the floating gate electrode 13 via the between-storage-layer-and-electrode insulating film 14, out of the voltage Vcg applied across the semiconductor substrate 11 and the control gate electrode 15.

Therefore, V1=(1−β)×Vcg, and V2=β×Vcg. Then, Equation (2) below is satisfied:

β=C1/(C1+C2) (2)

where C1 is the capacitance between the semiconductor substrate 11 and the floating gate electrode 13 and C2 is the capacitance between the floating gate electrode 13 and the control gate electrode 15.

Here, the equivalent thicknesses of the gate insulating film 12 and the between-storage-layer-and-electrode insulating film 14 are Teff1 and Teff2, and the leakage current densities thereof are J1 and J2. In order to transfer a charge between the control gate electrode 15 and the floating gate electrode 13 via the between-storage-layer-and-electrode insulating film 14, it is only necessary that the amount of a leakage current passing through the between-storage-layer-and-electrode insulating film 14 (S2×J2) be greater than the amount of a leakage current passing through the gate insulating film 12 (S1×J1) when the voltage Vcg is applied across the semiconductor substrate 11 and the control gate electrode 15. Area S1 is the area in which the semiconductor substrate 11 faces the floating gate electrode 13, and area S2 is the area in which the floating gate electrode 13 faces the control gate electrode 15.

In addition, in order to ensure high-speed memory operation and reliability, the difference should desirably be larger between the amount of the leakage current passing through the between-storage-layer-and-electrode insulating film 14 and the amount of the leakage current passing through the gate insulating film 12, and it is typically desirable that one be more than ten times the other.

When the interfaces of the semiconductor substrate 11, the floating gate electrode 13 and the control gate electrode 15 are flat, an electric field E1 applied to the gate insulating film 12 is expressed by Equation (3) below:

E1=(1−β)×Vcg/Teff1={C2/(C1+C2)}×Vcg/Teff1 (3)

Furthermore, an electric field E2 applied to the between-storage-layer-and-electrode insulating film 14 is expressed by Equation (4) below:

E2=β×Vcg/Teff2={C1/(C1+C2)}×Vcg/Teff (4)

The ratio of the capacitance C1 to the capacitance C2 is approximately expressed by Equation (5) below:

C1/C2=(S1×Teff2)/(S2×Teff1) (5)

Therefore, electric field E1 and electric field E2 are expressed by Equations (6) and (7) below:

E1={S2/(S1×Teff2+S2×Teff1)}×Vcg (6)

E2={S1/(S1×Teff2+S2×Teff1)}×Vcg (7)

In order to transfer a charge between the control gate electrode 15 and the floating gate electrode 13 via the between-storage-layer-and-electrode insulating film 14, it is only necessary to select the material and thickness of the gate insulating film 12 and the between-storage-layer-and-electrode insulating film 14 and the shape of the memory cell transistor (areas S1 and S2) in accordance with the applied voltage Vcg so that the product of leakage current density J2 and area S2 when electric field E2 expressed by Equation (4) or (7) is applied to the between-storage-layer-and-electrode insulating film 14 may be greater than the product of leakage current density J1 and area S1 when electric field E1 expressed by Equations (3) or (6) is applied to the gate insulating film 12.

In the memory cell transistor of the semiconductor memory according to the first embodiment, area S1 is equal to area S2 as shown in FIG. 3. Thus, it is only necessary to select the material and thickness of the gate insulating film 12 and the between-storage-layer-and-electrode insulating film 14 in accordance with the applied voltage Vcg.

A case will be described below where the electric field at the charge injection interface increases because the interfaces of the semiconductor substrate 11, the floating gate electrode 13 and the control gate electrode 15 are convex curved shapes.

Here, the ratio of an electric field in the case where the interface is convex to an electric field in the case where the interface is flat is defined as an electric field increase coefficient γ, and the electric field increase coefficients of the gate insulating film 12 and the between-storage-layer-and-electrode insulating film 14 are γ1 and γ2, respectively. An electric field E1a applied to the gate insulating film 12 and an electric field E2a applied to the between-storage-layer-and-electrode insulating film 14 are expressed by Equations (8) and (9) below:

E1a=γ1×{C2/(C1+C2)}×Vcg/Teff1 (8)

E2a=γ2×{C1/(C1+C2)}×Vcg/Teff2 (9)

In order to transfer a charge between the control gate electrode 15 and the floating gate electrode 13 via the between-storage-layer-and-electrode insulating film 14, it is only necessary to select the material and thickness of the gate insulating film 12 and the between-storage-layer-and-electrode insulating film 14, the shape of the memory cell transistor (areas S1 and S2, and the curved shape of the interface) and the applied voltage Vcg so that the product of leakage current density J2 and area S2 when electric field E2a is applied to the between-storage-layer-and-electrode insulating film 14 may be greater than the product of leakage current density J1 and area S1 when electric field E1a is applied to the gate insulating film 12.

Here, the electric field increase coefficient γ is expressed by γ=1+Teff/R when the convex curved surface is a concentric spherical surface with a curvature R and expressed by γ=1/{R/Teff×ln(1+Teff/R)} when the convex curved surface is a concentric cylindrical surface with the curvature R.

In addition, the thickness of the gate insulating film 12 of the cell transistor shown in FIG. 3 should desirably be set to a thickness at which a charge stored in the floating gate electrode 13 does not escape to the side of the semiconductor substrate 11 even if the charge is left as it is for a long time. The typical lower limit of the thickness of the gate insulating film 12 is about 5 nm in the case of the silicon oxide film, 5 to 8 nm in the case of the silicon oxynitride film (the equivalent thickness Teff is about 4.5 nm), and about 8 nm in the case of the silicon nitride film (the equivalent thickness Teff is about 4 nm).

As has been already described above, the typical thickness of the tunnel insulating film of the related art is 8 nm or more in the case of the silicon oxide film or the silicon oxynitride film, so that the thickness of the gate insulating film 12 can be smaller than that in the related art, and the applied voltage in the write and erase operations can be reduced.

For example, the write and erase operations can be performed with an applied voltage of about 10V in the memory cell transistor shown in FIG. 3. An operating voltage of about 10V is about half that in the related art. That is, according to the semiconductor memory in the first embodiment, it is possible to avoid problems such as decreased withstand voltage due to reduction in power consumption and increased integration of the memory.

The semiconductor memory according to the first embodiment can use the same operation method as that of the semiconductor memory of the related art when the negatively charged state of the floating gate electrode 13 is regarded as a positively charged state “1” of the semiconductor memory of the related art and the positively charged state of the floating gate electrode 13 is regarded as a negatively charged state “0” of the semiconductor memory of the related art. Alternatively, the electric field applied during the write and erase operations may be changed so that an electric field reverse to that of the related art is applied to perform the write and erase operations.

As described above, the semiconductor memory according to the first embodiment makes it possible to provide a memory cell transistor which transfers a charge between the floating gate electrode 13 and the control gate electrode 15 without introducing a complicated transistor structure and a complicated manufacturing process.

That is, no new gate electrode is required to control the transfer of the charge between the floating gate electrode 13 and the control gate electrode 15, and no complicated manufacturing process is required.

Furthermore, there arises no problem which makes it unsuitable for a high-speed operation because there is no parasitic capacitance between a newly added gate electrode and the control gate electrode 15.

Still further, it is possible to avoid deterioration in quality of the gate insulating film 12 due to the write and erase operations and achieve higher reliability of the memory cell transistor without increasing the parasitic capacitance of interconnects.

Further yet, as the thickness of the gate insulating film 12 of the memory cell transistor can be reduced, the position of a stored charge is closer to the surface of the substrate, and the threshold window of the memory cell transistor can be widened.

At the same time, it is possible to avoid the problem of a decreased operation speed of the peripheral circuit because the thickness of the gate insulating film 12 of the peripheral circuit transistor does not have to be large.

Also, it is possible to avoid the problem of a decreased operation speed of the selection of the memory cell transistor because the thickness of the gate insulating film 12 of the select transistor does not have to be large.

In addition, as a charge transfers between the control gate electrode 15 and the floating gate electrode 13 via the between-storage-layer-and-electrode insulating film 14, the quality of the between-storage-layer-and-electrode insulating film 14 can deteriorate. However, even if the charge is trapped in the between-storage-layer-and-electrode insulating film 14, the effect on the characteristics of the memory cell transistor is small and no characteristic problem of the semiconductor memory occurs because the distance from the channel region to the trap level is long.

Although the example in which the injected charge is an electron has been shown in the above explanation, a proper modification can be made in the case of a hole to obtain the above-mentioned effects according to the semiconductor memory in the first embodiment.

<Manufacturing Method>

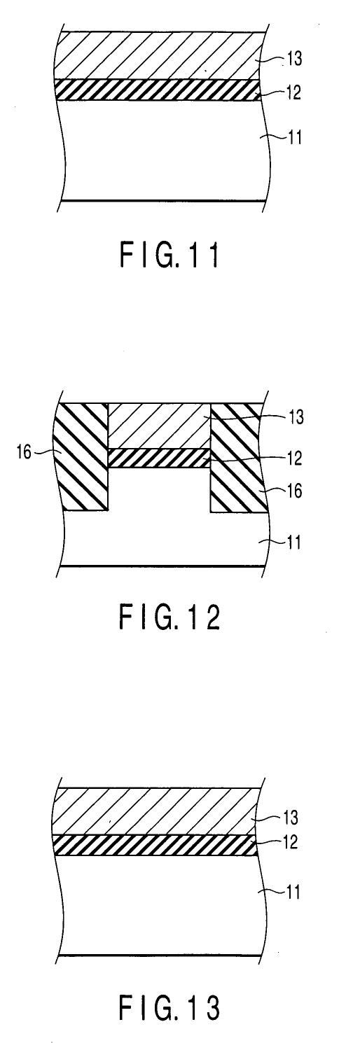

A method of manufacturing the semiconductor memory according to the first embodiment of the present invention will be described using FIGS. 11 to 28. It is to be noted that the semiconductor memory manufacturing method described below is merely illustrative, the semiconductor memory can also be provided by various other manufacturing methods including modifications of the present manufacturing method.

FIGS. 11, 14, 17, 20, 23 and 26 show process sectional views of the memory cell transistor sectioned along the channel length direction (the direction of bit lines BL₁, BL₂, BL₃, . . . , in FIG. 2) of the memory cell transistor. FIGS. 12, 15, 18, 21, 24 and 27 show process sectional views in the channel width direction (the direction of word lines WL₁, WL₂, WL₃, . . . , in FIG. 2) of the memory cell transistor. FIGS. 13, 16, 19, 22, 25 and 28 show process sectional views in the channel length direction of the peripheral circuit transistor. In addition, the select transistor is also formed in a process similar to that of the peripheral circuit transistor.

First, as shown in FIGS. 11 to 13, the gate insulating film 12 of the memory cell transistor and the peripheral circuit transistor which is a silicon oxynitride film is formed at a thickness of about 6 nm on the surface of the semiconductor substrate 11 made of a p-type silicon substrate using, for example, a thermal oxidation method and a radical nitriding method. Then, a doped silicon polycrystalline film doped with n-type impurities such as phosphorus (P) is formed as the floating gate electrode 13 at about 50 nm on the gate insulating film 12 using, for example, the low-pressure CVD method.

Furthermore, a photoresist film is applied to the floating gate electrode 13, and the photoresist film is exposed and developed by a photolithographic technique, such that an etching mask (not shown) for patterning an element formation region is formed. This etching mask is used to sequentially etch and remove parts of the floating gate electrode 13, the gate insulating film 12 and the semiconductor substrate 11 by the reactive ion etching (RIE) method, so that a trench serving as an isolation region is formed. After the removal of the etching mask, for example, a silicon oxide film is embedded in the trench using, for example, an application method and the chemical mechanical polishing (CMP) method, thereby forming an isolation insulating film 16. However, although not shown in FIG. 13, it should be understood that the isolation insulating film 16 is formed in the region of the peripheral circuit 20 as well.

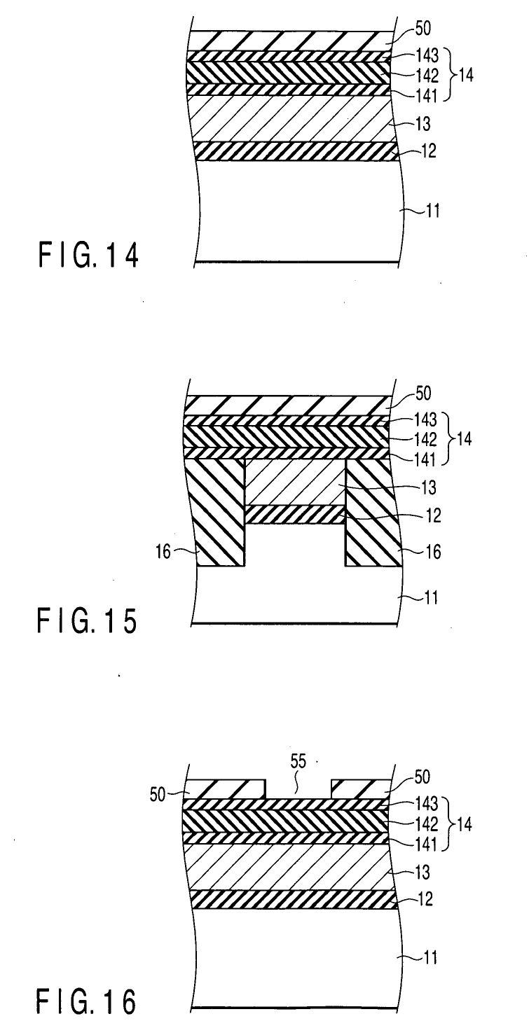

Next, as shown in FIGS. 14 to 16, a silicon oxide film about 1.3 nm thick as the first insulating film 141, an alumina film about 8 nm thick as the second insulating film 142 and a silicon oxide film about 1.3 nm thick as the third insulating film 143 are sequentially deposited on the floating gate electrode 13 and the isolation insulating film 16 by, for example, the low-pressure CVD method, thereby forming the between-storage-layer-and-electrode insulating film 14.

Then, a photoresist film 50 is applied to the entire surface. Further, the photoresist film 50 is exposed and developed by the photolithographic technique, and an opening 55 is formed in the photoresist film 50 as shown in FIG. 16 in a region where the gate electrode of the peripheral circuit transistor will be formed later.

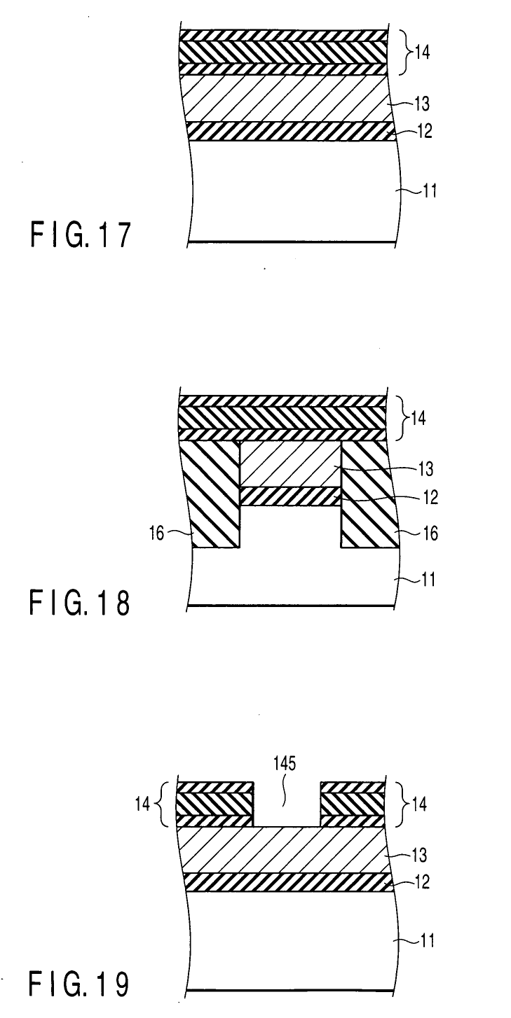

Subsequently, the between-storage-layer-and-electrode insulating film 14 is etched by the RIE method using the photoresist film 50 as an etching mask. Then, as shown in FIGS. 17 to 19, an opening 145 as shown in FIG. 19 is formed in the between-storage-layer-and-electrode insulating film 14 in the region where the gate electrode of the peripheral circuit transistor is scheduled to be formed. After this, the photoresist film is removed.

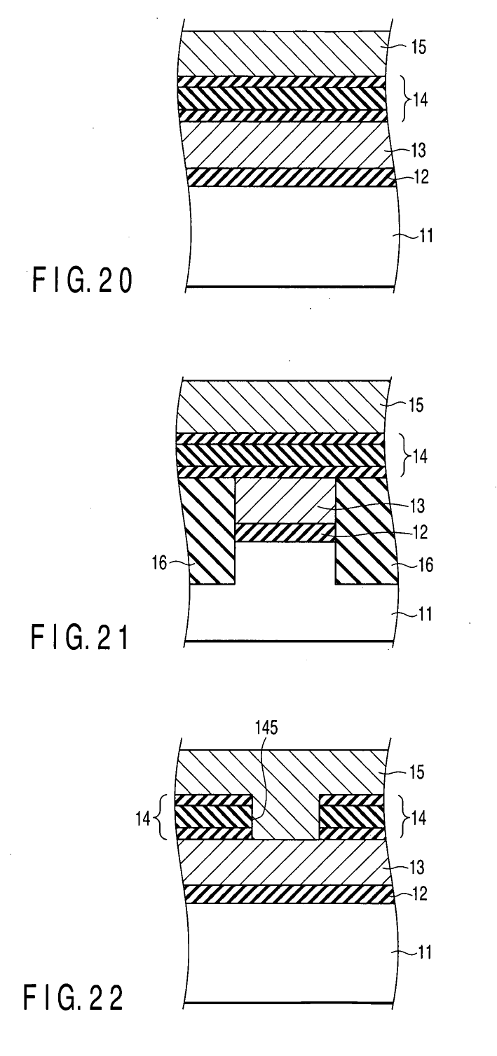

Then, as shown in FIGS. 20 to 22, a doped silicon polycrystalline layer doped with, for example, phosphorus which serves as the control gate electrode 15 is formed at a thickness of about 50 nm on the between-storage-layer-and-electrode insulating film 14 by, for example, the low-pressure CVD method. At the same time, as shown in FIG. 22, the floating gate electrode 13 is electrically connected to the control gate electrode 15 via the opening 145 in the peripheral circuit transistor. At this point, the surface of the control gate electrode in the opening region is slightly concave, but this shape is not shown in FIG. 22 for simplicity.

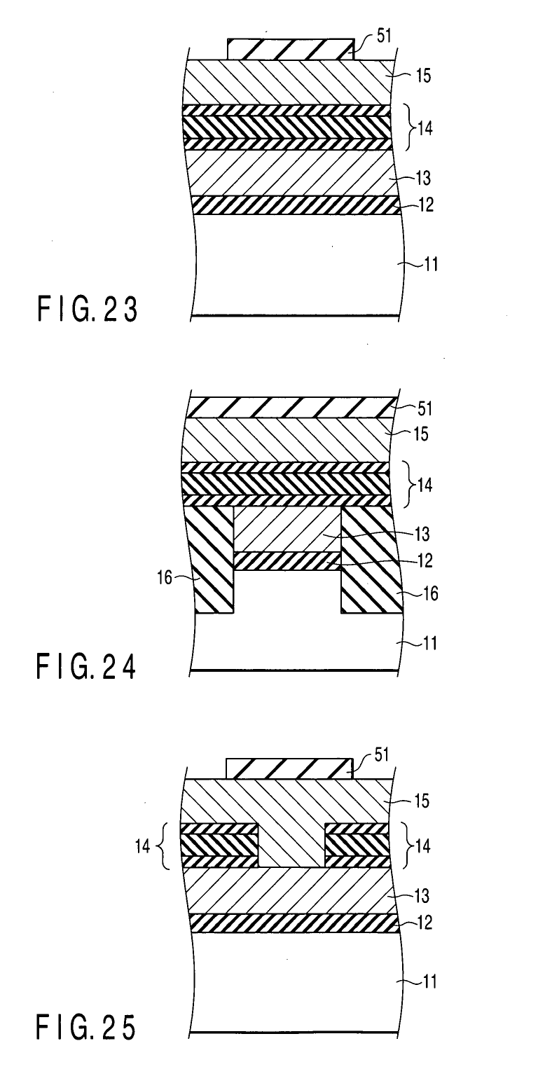

Then, as shown in FIGS. 23 to 25, a new photoresist film 51 is applied to the entire upper surface of the control gate electrode 15. The photoresist film 51 is exposed and developed by the photolithographic technique, and the photoresist film 51 is removed except for the region where the gate electrode is formed.

Subsequently, the photoresist film 51 is used as an etching mask to selectively etch and remove the control gate electrode 15, the between-storage-layer-and-electrode insulating film 14 and the floating gate electrode 13 by, for example, the RIE method, thereby forming the gate electrode of the memory cell transistor and the peripheral circuit transistor.

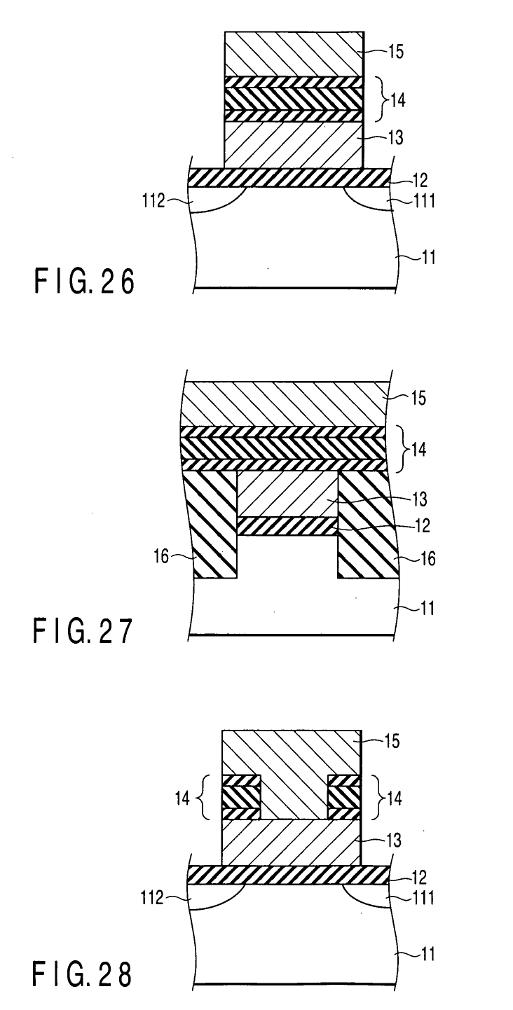

Then, as shown in FIGS. 26 to 28, an n-type impurity such as arsenic (As) is ion-implanted into the memory cell array 10 and the peripheral circuit 20, thereby forming the drain region 111 and the source region 112. Further, an interlayer insulating film (not shown) made of, for example, a silicon oxide film is deposited on the entire surface, which is followed by the formation of an interconnect layer, etc., such that the semiconductor memory according to the first embodiment is completed.

According to the semiconductor memory manufacturing method according to the first embodiment of the present invention as described above, it is possible to readily manufacture a memory cell transistor with a gate electrode structure having the between-storage-layer-and-electrode insulating film 14 in which the amount of a charge passing therethrough during the application of an electric field in the write and erase operations is greater than that in the gate insulating film 12.

Furthermore, according to the semiconductor memory manufacturing method in the first embodiment, the floating gate electrodes, the between-storage-layer-and-electrode insulating films and the control gate electrodes in the select transistor and the peripheral circuit transistor can be made with the same thickness and material as those in the memory cell transistor.

Therefore, the photolithographic process and the process using the CMP method or the RIE method are simpler, and a micro cell can be provided.

<Modification>

(a) First Modification

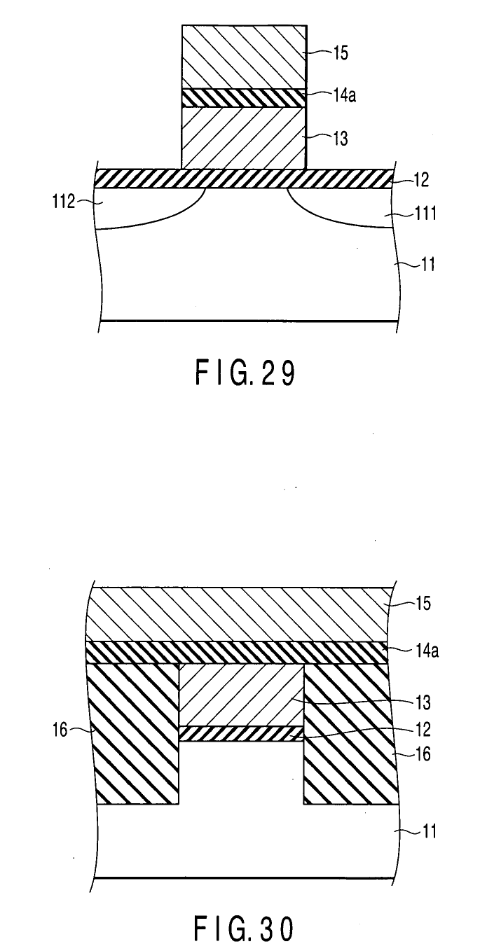

FIGS. 29 and 30 show schematic sectional view of a memory cell transistor of a semiconductor memory according to a first modification of the first embodiment.

FIG. 29 is a sectional view of the memory cell transistor sectioned along the channel length direction (the direction of bit lines BL₁, BL₂, BL₃, . . . , in FIG. 2) of the memory cell transistor. FIG. 30 is a sectional view in the channel width direction (the direction of word lines WL₁, WL₂, WL₃, . . . , in FIG. 2) of the memory cell transistor.

In the memory cell transistor shown in FIGS. 29 and 30, a silicon oxide film or silicon oxynitride film is employed for a between-storage-layer-and-electrode insulating film 14a, and a silicon nitride film formed by nitriding the surface of a silicon substrate through the radical nitriding method is employed for a gate insulating film 12. In the silicon nitride film formed in this method, the density of a charge trap level is lower than that in a silicon nitride film formed by the ordinary low-pressure CVD method, and the electric conduction efficiency can be lower than those in the silicon oxide film and silicon oxynitride film. Such a high-quality silicon nitride film can be obtained by nitriding a silicon layer using a nitrogen radical as the main nitriding species.

The between-storage-layer-and-electrode insulating film 14a of the memory cell transistor shown in FIGS. 29 and 30 is different from the between-storage-layer-and-electrode insulating film 14 of the memory cell transistor shown in FIG. 3 in that the between-storage-layer-and-electrode insulating film 14a is made of a single insulating film while the between-storage-layer-and-electrode insulating film 14 is made of a plurality of insulating films.

According to the structure shown in FIGS. 29 and 30, the electric conduction efficiency of the gate insulating film 12 made of the high-quality silicon nitride film can be lower than the electric conduction efficiency of the between-storage-layer-and-electrode insulating film made of the silicon oxide film or silicon oxynitride film, so that a charge can be transferred between a control gate electrode 15 and a floating gate electrode 13 via the between-storage-layer-and-electrode insulating film 14a in the memory cell transistor shown in FIGS. 29 and 30.

In particular, when the memory cell transistor structure shown in FIGS. 29 and 30 is employed, the material of the between-storage-layer-and-electrode insulating film 14a through which the charge passes is the same as the material of the gate insulating film (tunnel insulating film) of the related art, so that it is easy to ensure the reliability of the semiconductor memory equal to that in the related art.

In addition, the silicon nitride film formed by the radical nitriding method is used as the gate insulating film 12 in the present modification, but this is not a limitation, and other materials formed by other methods can also be employed for the gate insulating film 12 as long as the electric conduction efficiency of such materials is lower than that of the silicon oxide film or silicon oxynitride film used for the between-storage-layer-and-electrode insulating film 14a.

Moreover, in order to manufacture the memory cell transistor shown in FIGS. 29 and 30, the between-storage-layer-and-electrode insulating film 14a can be formed using a single material in the manufacturing method described with reference to FIGS. 11 and 28.

(b) Second Modification

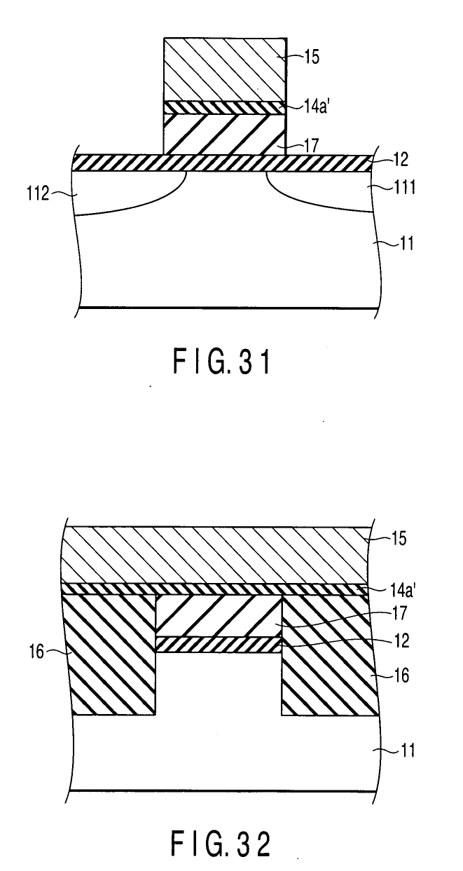

FIGS. 31 and 32 show schematic sectional views of a memory cell transistor of a semiconductor memory according to a second modification of the first embodiment.

FIG. 31 is a sectional view of the memory cell transistor sectioned along the channel length direction (the direction of bit lines BL₁, BL₂, BL₃, . . . , in FIG. 1) of the memory cell transistor. FIG. 32 is a sectional view in the channel width direction (the direction of word lines WL₁, WL₂, WL₃, . . . , in FIG. 2) of the memory cell transistor.

The memory cell transistor using the floating gate electrode 13 made of a polysilicon film as the charge storage layer has been described in the examples shown in FIGS. 3, 29 and 30. However, the first embodiment of the present invention is not limited to this, and as in the present modification, it is also possible to use a memory cell transistor with a MONOS structure in which an insulating film such as a silicon nitride film serves as the charge storage layer.

In the MONOS type memory cell transistor as shown in FIGS. 31 and 32, the materials and thicknesses of a between-storage-layer-and-electrode insulating film 14a′ and a gate insulating film 12 are combined so that the tunnel effect of the between-storage-layer-and-electrode insulating film 14a′ is more evident than the tunnel effect of the gate insulating film 12. For example, the materials and thicknesses of the between-storage-layer-and-electrode insulating film and the gate insulating film can be used which are similar to those in the first embodiment and the first modification described above. In particular, a highly reliable memory cell transistor can be provided if a silicon oxide film or silicon oxynitride film is used for the between-storage-layer-and-electrode insulating film and a silicon nitride film with low density of a charge trap level formed by, for example, the radical nitriding method is used for the gate insulating film.

Thus, the electric conduction efficiency of the between-storage-layer-and-electrode insulating film 14a′ can be higher than the electric conduction efficiency of the gate insulating film 12 in connection with an applied electric field during write and erase.

Therefore, in the present modification as well, the amount of a charge transferring between an insulating film 17 and a control gate electrode 15 via the between-storage-layer-and-electrode insulating film 14a′ can be sufficiently greater than the amount of a charge transferring between a channel region in a semiconductor substrate 11 and the insulating film 17 via the gate insulating film 12 when a high electric field is applied across the semiconductor substrate 11 and the control gate electrode 15. That is, the between-storage-layer-and-electrode insulating film 14a′ can function as a tunnel insulating film.

As described above, the charge storage layer of the memory cell transistor shown in FIGS. 31 and 32 is different from the charge storage layer of the memory cell transistor shown in FIGS. 3, 29 and 30 in that the charge storage layer in the second modification of the first embodiment is made of an insulating film while the charge storage layer in FIGS. 3, 29 and 30 is the floating gate electrode made of polysilicon.

As in the present modification, the charge is trapped by the charge trap level in the insulating film as the charge storage layer in the memory cell transistor with the MONOS structure. Thus, the leakage of the stored charge to the semiconductor substrate side or the control gate electrode side is smaller than the leakage of the charge stored in a conductive layer such as the polysilicon layer.

Consequently, the thickness of the gate insulating film can be smaller than the thickness of the gate insulating film of the memory cell transistor using the conductive layer such as the polysilicon layer as the charge storage layer, and an applied voltage during the write and data erase operations can be reduced.

In particular, when the memory cell transistor structure shown in FIGS. 31 and 32 is employed, the thickness of the gate insulating film 12 of the memory cell transistor can be reduced, so that the position of the stored charge is closer to the surface of the substrate, and the threshold window of the memory cell transistor can be widened.

Furthermore, the charge storage layer made of the insulating film is used, such that the thickness of the charge storage layer can be smaller than that of the charge storage layer made of the conductive layer such as the polysilicon film, thereby enabling the miniaturization of the memory cell transistor.

In addition, the present modification can employ either a single layer structure or a stacked structure for the between-storage-layer-and-electrode insulating film 14a′ as long as the electric conduction efficiency is higher than the electric conduction efficiency of the gate insulating film 12.

Moreover, the silicon nitride film is used as the insulating film serving as the charge storage layer in the present modification, but this is not a limitation, and other materials may be employed as long as they serve as insulating films capable of trapping a charge by the charge trap level in the film.

In addition, in order to manufacture the memory cell transistor shown in FIGS. 31 and 32, for example, the insulating film 17 made of the silicon nitride film can be formed as the charge storage layer instead of the floating gate electrode made of the polysilicon film in the manufacturing method described with reference to FIGS. 11 and 28.

### Second Embodiment

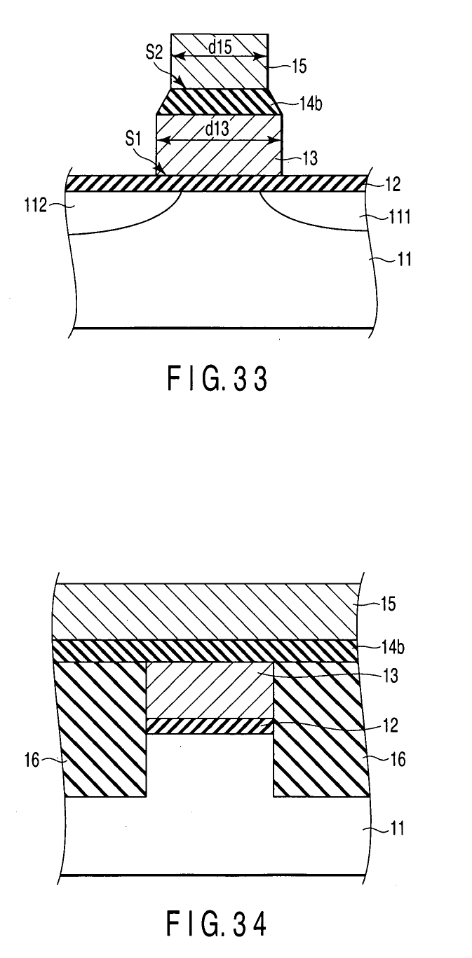

FIG. 33 shows a schematic sectional view of a memory cell transistor of a semiconductor memory according to a second embodiment of the present invention. FIG. 33 is a sectional view of the memory cell transistor sectioned along the channel length direction (the direction of bit lines BL₁, BL₂, BL₃, . . . , in FIG. 1) of the memory cell transistor. FIG. 34 is a sectional view in the channel width direction (the direction of word lines WL₁, WL₂, WL₃, . . . , in FIG. 1) of the memory cell transistor.

As shown in FIGS. 33 and 34, a length d15 in the channel length direction of a control gate electrode 15 is smaller than a length d13 in the channel length direction of a floating gate electrode 13, so that a between-storage-layer-and-electrode insulating film 14b forms a trapezoidal cross section along the channel length direction of the memory cell transistor.

Thus, an area S2 in which the control gate electrode 15 faces the floating gate electrode 13 is smaller than an area S1 in which the floating gate electrode 13 faces a semiconductor substrate 11.

The configuration is similar to that of the memory cell transistor according to the first embodiment shown in FIG. 3 in other respects, and is therefore not described in detail.

In order to transfer a charge between the control gate electrode 15 and the floating gate electrode 13 via the between-storage-layer-and-electrode insulating film 14b, it is only necessary that the amount of a leakage current passing through the between-storage-layer-and-electrode insulating film 14b (S2×J2) be greater than the amount of a leakage current passing through the gate insulating film 12 (S1×J1) when a voltage Vcg is applied across the semiconductor substrate 11 and the control gate electrode 15. Here, J1 and J2 are the densities of the leakage currents in the gate insulating film 12 and the between-storage-layer-and-electrode insulating film 14b, respectively.

As described using Equation (2) to Equation (7) in the first embodiment, it is only necessary, in the present embodiment as well, to select the materials and thickness of the gate insulating film 12 and the between-storage-layer-and-electrode insulating film 14b and the shape of the memory cell transistor (areas S1 and S2) so that the product of the leakage current density J2 and the area S2 when electric field E2 indicated in Equation (4) or Equation (7) is applied to the between-storage-layer-and-electrode insulating film 14b may be greater than the product of the leakage current density J1 and area S1 when electric field E1 indicated in Equation (3) or Equation (6) is applied to the gate insulating film 12. Thus, the charge transfers between the control gate electrode 15 and the floating gate electrode 13 via the between-storage-layer-and-electrode insulating film 14b.

In the memory cell transistor shown in FIGS. 33 and 34, area S2 is smaller than area S1, so that electric field E2 applied to the between-storage-layer-and-electrode insulating film 14b can be stronger than electric field E1 applied to the gate insulating film 12 when the voltage Vcg is applied across the semiconductor substrate 11 and the control gate electrode 15.

Specifically, since S1>S2 increases the ratio of the capacitances C1/C2, the voltage division factor β (β=V2/Vcg) increases. As a result, in the memory cell transistor shown in FIGS. 33 and 34, electric field E2 applied to the between-storage-layer-and-electrode insulating film 14b can be stronger and electric field E1 applied to the gate insulating film 12 can be weaker.

Therefore, the charge can be transferred between the control gate electrode 15 and the floating gate electrode 13 via the between-storage-layer-and-electrode insulating film 14b to carry out the write and erase operations.

Assume that the gate insulating film 12 and the between-storage-layer-and-electrode insulating film 14b are made of the same material in the memory cell transistor shown in FIGS. 33 and 34. For example, the gate insulating film 12 and the between-storage-layer-and-electrode insulating film 14b are made of silicon oxide films, and both of them have a thickness of 5.4 nm.

The electric conduction characteristics of the silicon oxide film having a thickness of 5.4 nm are shown by the leakage current density as curve C in FIG. 5. At this point, the voltage division factor β is 0.55 if the ratio of the facing areas S1/S2 of the memory cell transistor is 1.2.

Thus, if the applied voltage Vcg is set at 10V or more, a voltage of 5.5V or more is applied to the between-storage-layer-and-electrode insulating film 14b and a voltage of 4.5V or more is applied to the gate insulating film 12. As a result, the equivalent electric fields of the between-storage-layer-and-electrode insulating film 14b and the gate insulating film 12 are 10.2 MV/cm or more and 8.3 MV/cm or more, respectively.

Thus, the leakage current in the between-storage-layer-and-electrode insulating film 14b can be increased more than about ten more times as high as the leakage current in the gate insulating film 12.

It goes without saying that the material of the gate insulating film 12 does not have to be the same as the material of the between-storage-layer-and-electrode insulating film 14b, and the between-storage-layer-and-electrode insulating film 14b should desirably be made of a material whose electric conduction efficiency is higher than that of the gate insulating film 12. For example, the between-storage-layer-and-electrode insulating film 14 with the stacked structure shown in FIG. 3 may be employed as the between-storage-layer-and-electrode insulating film 14b.

Furthermore, the thicknesses (the equivalent silicon oxide thicknesses) of the gate insulating film 12 and the between-storage-layer-and-electrode insulating film 14b do not have to be the same, and it is desirable that the thickness (the equivalent silicon oxide thickness) of the between-storage-layer-and-electrode insulating film 14b be larger than that of the gate insulating film 12 because the electric fields applied through the division of a voltage are higher.

Still further, if the ratio of the facing areas S1/S2 is higher than 1, there is an effect of increasing the leakage current in the between-storage-layer-and-electrode insulating film 14b. However, it is desirable that the ratio of the facing areas S1/S2 be higher than 1.1 in order to transfer a charge between the control gate electrode 15 and the floating gate electrode 13 via the between-storage-layer-and-electrode insulating film 14b to carry out the write and erase operations.

Further yet, it is desirable that the ratio of the facing areas S1/S2 be higher than 1.2 in order to increase the amount of the leakage current in the between-storage-layer-and-electrode insulating film 14b about ten times as high as that in the gate insulating film 12 to achieve a high-speed operation enough for a semiconductor memory while avoiding the deterioration in quality of the gate insulating film 12.

The example of the memory cell transistor has been described above where the cross section of the between-storage-layer-and-electrode insulating film 14b along the channel length direction is trapezoidal. In order to transfer a charge between the control gate electrode 15 and the floating gate electrode 13 via the between-storage-layer-and-electrode insulating film 14b to carry out the write and erase operations, it is only necessary to provide a memory cell transistor wherein area S2 in which the control gate electrode 15 faces the floating gate electrode 13 is smaller than area S1 in which the floating gate electrode 13 faces a semiconductor substrate 11, without limiting to the memory cell transistor shown in FIGS. 33 and 34, and various modifications can be employed.

According to the semiconductor memory in the second embodiment of the present invention, the ratio of the facing areas S1/S2 of the memory cell transistor is higher than 1, such that the amount of the charge passing through the between-storage-layer-and-electrode insulating film 14b during the application of an electric field in the write and erase operations of the semiconductor memory can be greater than that in the gate insulating film 12. Thus, the charge can be transferred between the control gate electrode 15 and the floating gate electrode 13 via the between-storage-layer-and-electrode insulating film 14b to carry out the write and erase operations. The second embodiment is substantially similar to the first embodiment in other respects, and repeated descriptions are omitted.

<Manufacturing Method>

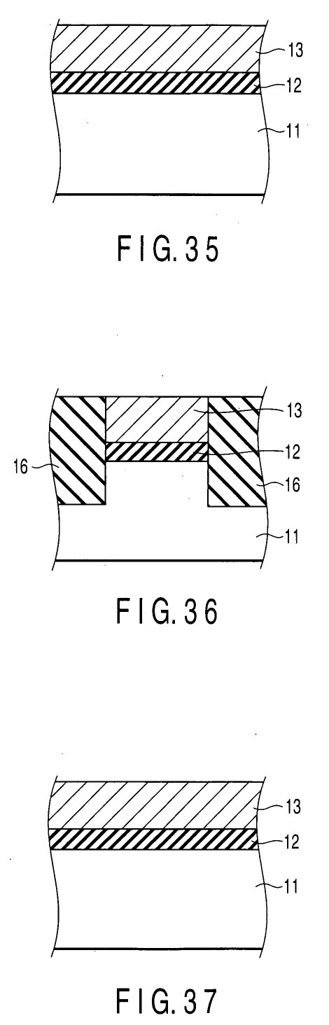

A method of manufacturing the semiconductor memory according to the second embodiment of the present invention will be described using FIG. 35 to FIG. 43. It is to be noted that the semiconductor memory manufacturing method described below is merely illustrative, the semiconductor memory can also be provided by various other manufacturing methods including modifications of the present manufacturing method.

FIGS. 35, 38 and 41 show process sectional views of the memory cell transistor sectioned along the channel length direction (the direction of bit lines BL₁, BL₂, BL₃, . . . , in FIG. 2) of the memory cell transistor. FIGS. 36, 39 and 42 show process sectional views in the channel width direction (the direction of word lines WL₁, WL₂, WL₃, . . . , in FIG. 2) of the memory cell transistor. FIGS. 37, 40 and 43 show process sectional views in the channel length direction of the peripheral circuit transistor. In addition, the select transistor is also formed in a process similar to that of the peripheral circuit transistor.

First, as shown in FIGS. 35 to 37, the gate insulating film 12 and the floating gate electrode 13 of the memory cell transistor and the peripheral circuit transistor which are deposited on the surface of the semiconductor substrate 11 are sequentially etched and removed in part, and part of the semiconductor substrate 11 is further etched and removed, such that a trench serving as an isolation region is formed, as in the semiconductor memory manufacturing method according to the first embodiment. Then, for example, a silicon oxide film is embedded in the trench using, for example, the CMP method, thereby forming an isolation insulating film 16. Although not shown, it should be understood that the isolation insulating film 16 is formed in the region of the peripheral circuit 20 as well.

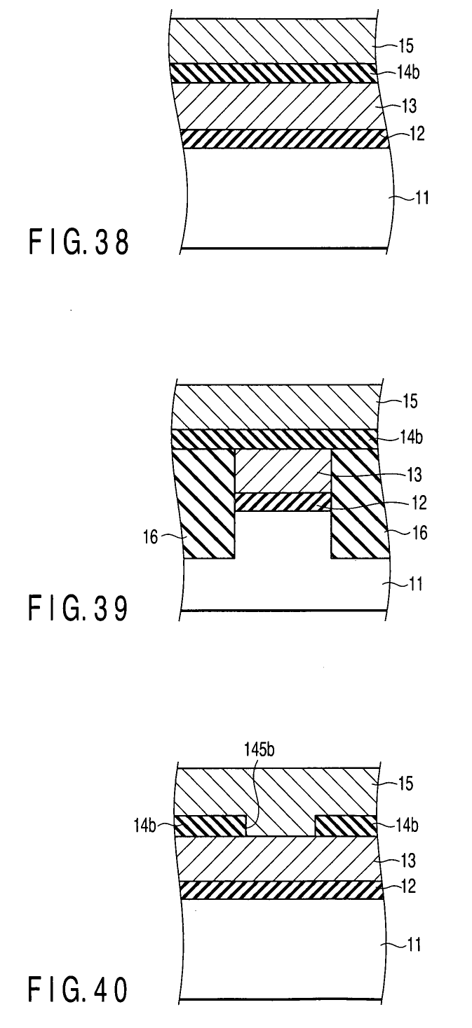

Then, as shown in FIGS. 38 to 40, a silicon oxide film as the between-storage-layer-and-electrode insulating film 14b is deposited at a thickness of, for example, about 6 nm on the floating gate electrode 13 and the isolation insulating film 16 by, for example, the low-pressure CVD method. Further, a photoresist film is exposed, developed and patterned by the photolithographic technique.

Using this photoresist film as an etching mask, an opening 145b is formed by the RIE method in the region where the gate electrode of the peripheral circuit transistor is scheduled to be formed. Then, a doped silicon polycrystalline layer doped with, for example, phosphorus which serves as the control gate electrode 15 is formed at a thickness of about 50 nm on the between-storage-layer-and-electrode insulating film 14b by, for example, the low-pressure CVD method. At the same time, as shown in FIG. 40, the floating gate electrode 13 is electrically connected to the control gate electrode 15 via the opening 145b in the peripheral circuit transistor.

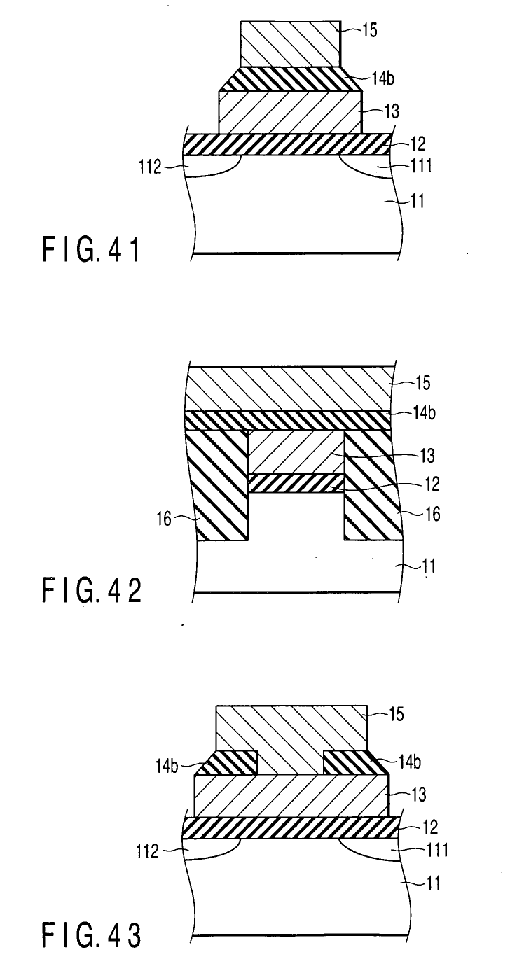

Then, a photoresist film is exposed, developed and patterned by the photolithographic technique. Further, this photoresist film is used as an etching mask to selectively etch and remove the control gate electrode 15, the between-storage-layer-and-electrode insulating film 14b and the floating gate electrode 13 by the RIE method, thereby forming the gate electrode of the memory cell transistor and the peripheral circuit transistor. At this point, the between-storage-layer-and-electrode insulating film 14b is etched by the RIE method under the condition of taper etching using a so-called sidewall protective film so that the end of the between-storage-layer-and-electrode insulating film 14b is etched into a forward mesa tapered cross section along the channel length direction. Consequently, as shown in FIGS. 41 to 43, the trapezoidal between-storage-layer-and-electrode insulating film 14b is formed.

Then, as shown in FIGS. 33 and 34, an n-type impurity is ion-implanted into the memory cell array 10 and the peripheral circuit 20, thereby forming a drain region 111 and a source region 112. Further, an interlayer insulating film (not shown) made of, for example, a silicon oxide film is deposited on the entire surface, which is followed by the formation of an interconnect layer, etc., such that the semiconductor memory according to the second embodiment is completed.

According to the semiconductor memory manufacturing method according to the second embodiment of the present invention, the between-storage-layer-and-electrode insulating film 14b is formed which has a trapezoidal cross section along the channel length direction of the memory cell transistor, whereby a semiconductor memory can be manufactured so that the area in which the between-storage-layer-and-electrode insulating film 14b contacts the control gate electrode 15 is larger than the area in which the between-storage-layer-and-electrode insulating film 14b contacts the floating gate electrode 13.

That is, the ratio of the facing areas S1/S2 of the memory cell transistor is higher than 1, such that the amount of the charge passing through the between-storage-layer-and-electrode insulating film 14b during the application of an electric field in the write and erase operations of the semiconductor memory can be greater than that in the gate insulating film 12.

Thus, it is possible to manufacture a semiconductor memory which transfers a charge between the control gate electrode 15 and the floating gate electrode 13 via the between-storage-layer-and-electrode insulating film 14b to perform the write and erase operations.

Furthermore, according to the semiconductor memory manufacturing method in the second embodiment, the control gate electrode 15, the between-storage-layer-and-electrode insulating film 14b and the floating gate electrode 13 can be formed by one etching mask.

Still further, according to the semiconductor memory manufacturing method in the second embodiment, the thickness of the gate insulating film of the memory cell transistor can be reduced. Thus, the position of the stored charge is closer to the surface of the substrate, and the threshold window of the memory cell transistor can be widened.

<Modification>

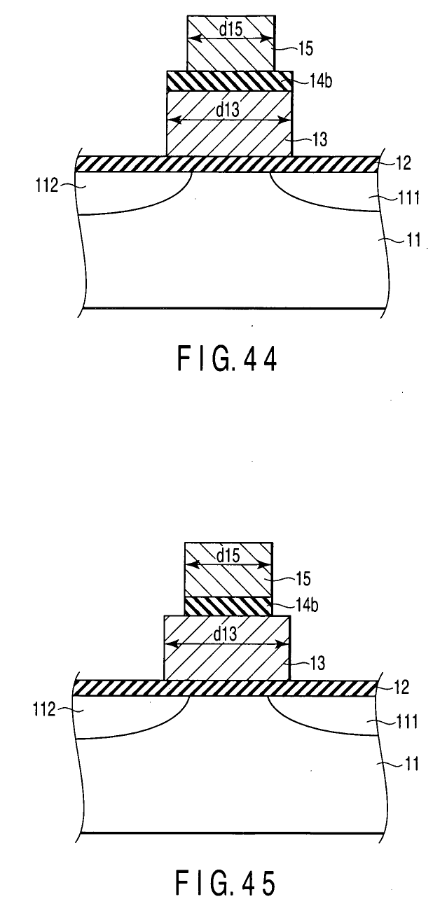

FIGS. 44 and 45 show sectional views of a memory cell transistor of a semiconductor memory according to a modification of the second embodiment in a cross section along the channel length direction. In the memory cell transistor shown in FIGS. 44 and 45, a length d15 in the channel length direction of a control gate electrode 15 is smaller than a length d13 in the channel length direction of a floating gate electrode 13.

Furthermore, the cross section along the channel length direction of a between-storage-layer-and-electrode insulating film 14b of the memory cell transistor shown in FIG. 44 is rectangular, and the dimension in the channel length direction is equal to d13.

Moreover, the cross section along the channel length direction of the between-storage-layer-and-electrode insulating film 14b of the memory cell transistor shown in FIG. 45 is rectangular, and the dimension in the channel length direction is equal to d15.

That is, in the memory cell transistor shown in FIGS. 44 and 45, the ratio of the facing areas S1/S2 is higher than 1, and a charge transfers between the control gate electrode 15 and the floating gate electrode 13 via the between-storage-layer-and-electrode insulating film 14b.

The gate electrode of the memory cell transistor shown in FIG. 44 can be formed by forming an etching mask having a width corresponding to the difference between the dimensions d13 and d15 on the sidewalls of the control gate electrode 15 after the selective etching and removal of the control gate electrode 15 and using this etching mask to selectively etch and remove the between-storage-layer-and-electrode insulating film 14b and the floating gate electrode 13.

Furthermore, the gate electrode of the memory cell transistor shown in FIG. 45 can be formed by forming an etching mask having a width corresponding to the difference between the dimensions d13 and d15 on the sidewalls of the control gate electrode 15 and the between-storage-layer-and-electrode insulating film 14b after the selective etching and removal of the control gate electrode 15 and the between-storage-layer-and-electrode insulating film 14b and using this etching mask to selectively etch and remove the floating gate electrode 13.

### Third Embodiment

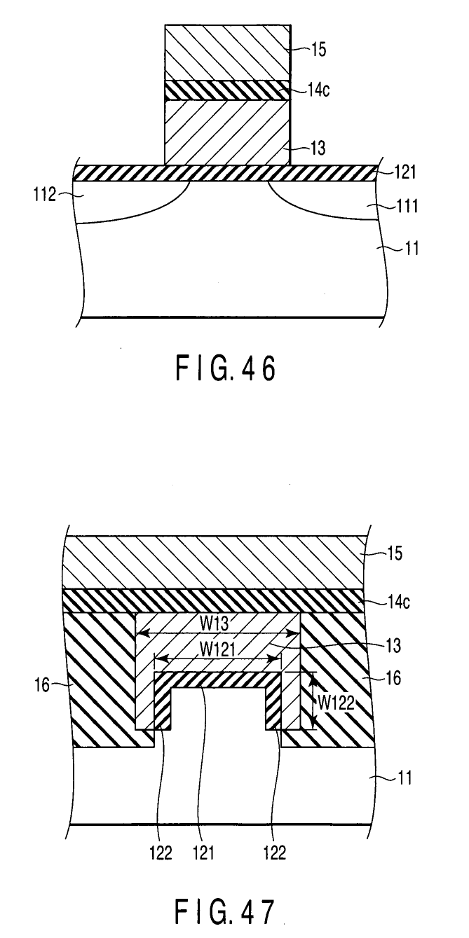

FIGS. 46 and 47 show schematic sectional views of a memory cell transistor of a semiconductor memory according to a third embodiment of the present invention.

FIG. 46 is a sectional view of the memory cell transistor sectioned along the channel length direction (the direction of bit lines BL₁, BL₂, BL₃, . . . , in FIG. 1) of the memory cell transistor. FIG. 47 is a sectional view in the channel width direction (the direction of word lines WL₁, WL₂, WL₃, . . . , in FIG. 1) of the memory cell transistor.

As shown in FIG. 47, in the memory cell transistor according to the third embodiment of the present invention, a gate insulating film 12 is disposed on the upper parts of the sidewalls of a projection formed at the top of a semiconductor substrate 11 and on the top surface of the projection.

This gate insulating film 12 is composed of a parallel gate insulating film 121 and vertical gate insulating films 122. The interface between the parallel gate insulating film 121 and a floating gate electrode 13 is parallel to the interface between a between-storage-layer-and-electrode insulating film 14c and the floating gate electrode 13. The vertical gate insulating films 122 connect to the ends of the parallel gate insulating film 121, and the interface between the vertical gate insulating films 122 and the floating gate electrode 13 is vertical to the interface between the between-storage-layer-and-electrode insulating film 14c and the floating gate electrode 13.

In the memory cell transistor shown in FIGS. 46 and 47, a length W122 is set so that W13<W121+2×W122 where W13 is the dimension of the floating gate electrode 13 in the channel width direction, W121 is the dimension of the parallel gate insulating film 121 in the channel width direction, and W122 is the dimension of the vertical gate insulating film 122 in a depth direction.

Thus, an area S2 in which the control gate electrode 15 faces the floating gate electrode 13 is smaller than an area S1 in which the floating gate electrode 13 faces the semiconductor substrate 11. In addition, the configuration is similar in other respects to that of the memory cell transistor according to the first embodiment shown in FIG. 3.

As has been already described above in the first embodiment, in order to transfer a charge between the control gate electrode 15 and the floating gate electrode 13 via the between-storage-layer-and-electrode insulating film 14c, it is only necessary that the amount of a leakage current passing through the between-storage-layer-and-electrode insulating film 14b (S2×J2) be greater than the amount of a leakage current passing through the gate insulating film 12 (S1×J1) when a voltage Vcg is applied across the semiconductor substrate 11 and the control gate electrode 15. Here, J1 and J2 are the densities of the leakage currents in the gate insulating film 12 and the between-storage-layer-and-electrode insulating film 14c, respectively.

In the memory cell transistor shown in FIGS. 46 and 47, area S2 is smaller than area S1, so that an electric field E2 applied to the between-storage-layer-and-electrode insulating film 14c can be stronger than an electric field E1 applied to the gate insulating film 12 when the voltage Vcg is applied across the semiconductor substrate 11 and the control gate electrode 15.

Specifically, since S1>S2 increases the ratio of the capacitances C1/C2, the voltage division factor β (β=V2/Vcg) increases. As a result, in the memory cell transistor shown in FIGS. 46 and 47, electric field E2 applied to the between-storage-layer-and-electrode insulating film 14c can be stronger and electric field E1 applied to the gate insulating film 12 can be weaker.

Therefore, the charge can be transferred between the control gate electrode 15 and the floating gate electrode 13 via the between-storage-layer-and-electrode insulating film 14b to carry out the write and erase operations.

In addition, the material of the gate insulating film 12 does not have to be the same as the material of the between-storage-layer-and-electrode insulating film 14c, and the between-storage-layer-and-electrode insulating film 14c should desirably be made of a material whose electric conduction efficiency is higher than that of the gate insulating film 12.

For example, the between-storage-layer-and-electrode insulating film 14 with the stacked structure shown in FIG. 3 may be employed instead of the between-storage-layer-and-electrode insulating film 14b. Moreover, the thicknesses (the equivalent silicon oxide thicknesses) of the gate insulating film 12 and the between-storage-layer-and-electrode insulating film 14c do not have to be the same, and it is desirable that the thickness (the equivalent silicon oxide thickness) of the between-storage-layer-and-electrode insulating film 14c be larger than that of the gate insulating film 12 because the electric fields applied through the division of a voltage are higher. The third embodiment is substantially similar to the first and second embodiments in other respects, and repeated descriptions are omitted.

<Manufacturing Method>

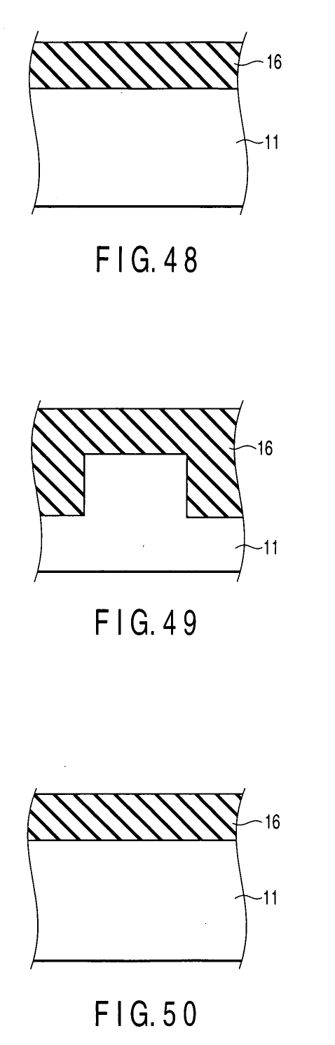

A method of manufacturing the semiconductor memory according to the third embodiment of the present invention will be described using FIG. 48 to FIG. 62. It is to be noted that the semiconductor memory manufacturing method described below is merely illustrative, the semiconductor memory can also be provided by various other manufacturing methods including modifications of the present manufacturing method. As in the semiconductor memory manufacturing methods according to the first and second embodiments, FIGS. 48, 51, 54, 57 and 60 show process sectional views of the memory cell transistor sectioned along the channel length direction (the direction of bit lines BL₁, BL₂, BL₃, . . . , in FIG. 1) of the memory cell transistor. FIGS. 49, 52, 55, 58 and 61 show process sectional views in the channel width direction (the direction of word lines WL₁, WL₂, WL₃, . . . , in FIG. 1) of the memory cell transistor. FIGS. 50, 53, 56, 59 and 62 show process sectional views in the channel length direction of the peripheral circuit transistor. In addition, the select transistor is also formed in a process similar to that of the peripheral circuit transistor.

First, as shown in FIGS. 48 to 50, a photoresist film (not shown) is applied to the surface of the semiconductor substrate 11 made of a p-type silicon substrate. The photoresist film is exposed and developed by the photolithographic technique, such that an etching mask (not shown) for patterning an element formation region is formed.

This etching mask is used to etch and remove part of the semiconductor substrate 11 by the RIE method, so that a trench serving as an isolation region is formed. Then, a silicon oxide film is deposited as the isolation insulating film 16 on the semiconductor substrate 11.

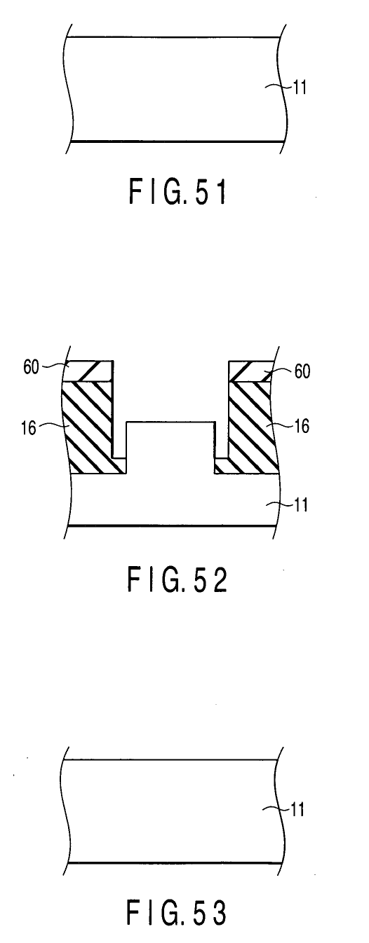

Then, a new photoresist film is applied to the isolation insulating film 16, and this photoresist film is exposed and developed by the photolithographic technique. Thus, as shown in FIGS. 51 to 53, an etching mask 60 for patterning an element formation region is formed.

The isolation insulating film 16 is etched by the RIE method using the etching mask 60, such that the upper parts of the sidewalls of the projection at the top of the semiconductor substrate 11 and the top surface of the projection are exposed in the region where the gate insulating film 12 is scheduled to be formed, as shown in FIG. 52.

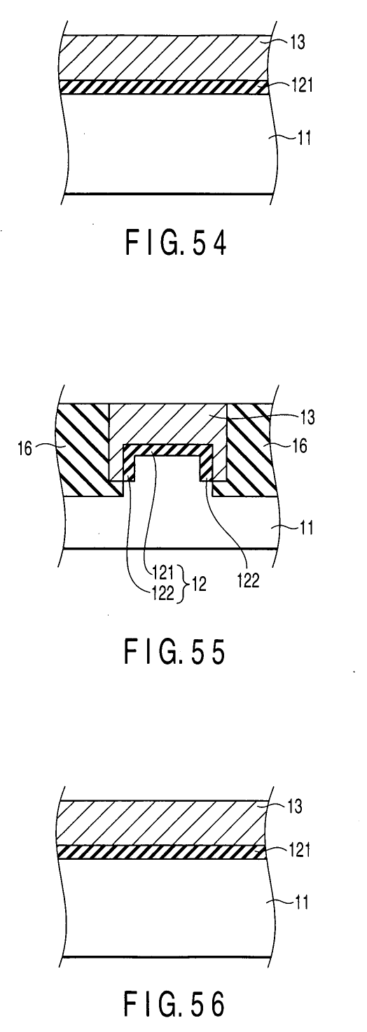

After the etching mask 60 is removed, the gate insulating film 12 made of, for example, a silicon oxynitride film is formed at a thickness of about 6 nm on the top surface and upper parts of the sidewalls of the projection formed at the top of the semiconductor substrate 11 by use of, for example, the thermal oxidation method, as shown in FIGS. 54 to 56.

Then, a doped silicon polycrystalline film doped with n-type impurities such as phosphorus is deposited as the floating gate electrode 13 on the gate insulating film 12 using, for example, the low-pressure CVD method. Further, the surface of the floating gate electrode 13 is removed using, for example, the CMP method until the top surface of the isolation insulating film 16 is exposed, such that the surface of the floating gate electrode 13 is planarized.

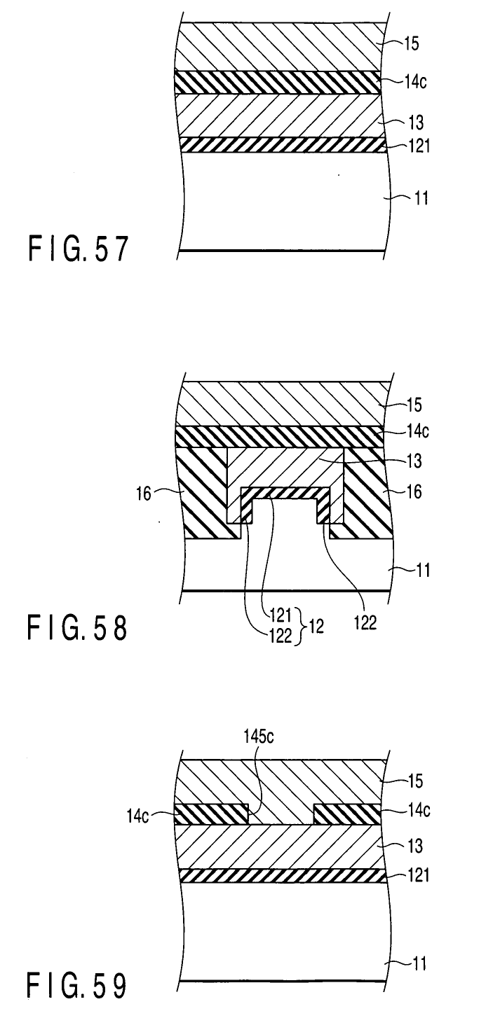

Then, as shown in FIGS. 57 to 59, a silicon oxide film as the between-storage-layer-and-electrode insulating film 14c is deposited at a thickness of, for example, about 6 nm all over the floating gate electrode 13 and the isolation insulating film 16 by, for example, the low-pressure CVD method. Further, a photoresist film is exposed, developed and patterned by the photolithographic technique. Using this photoresist film (not shown) as an etching mask, an opening 145c is formed by, for example, the RIE method in the region of the peripheral circuit transistor shown in FIG. 59 where the gate electrode is scheduled to be formed.

After the photoresist film is removed, a doped silicon polycrystalline layer doped with, for example, phosphorus which serves as the control gate electrode 15 is formed at a thickness of about 50 nm all over the between-storage-layer-and-electrode insulating film 14c by, for example, the low-pressure CVD method. At the same time, as shown in FIG. 59, the floating gate electrode 13 is electrically connected to the control gate electrode 15 via the opening 145c in the peripheral circuit transistor.

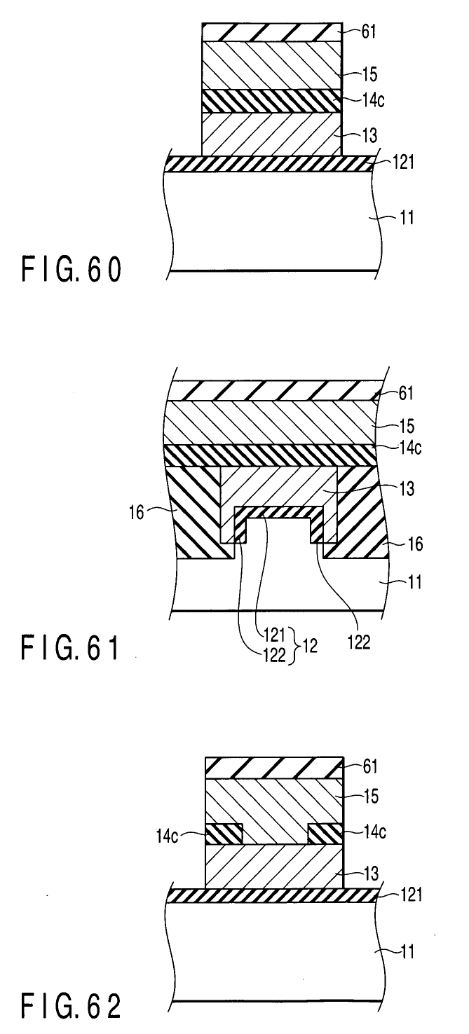

Then, as shown in FIGS. 60 to 62, a new photoresist film is patterned by the photolithographic technique, thereby forming an etching mask 61. Further, using the etching mask 61 as a mask, the control gate electrode 15, the between-storage-layer-and-electrode insulating film 14c and the floating gate electrode 13 are selectively etched by the RIE method, thereby forming the gate electrode of the memory cell transistor and the peripheral circuit transistor.

Furthermore, after the etching mask 61 is removed, an n-type impurity is ion-implanted into the memory cell array 10 and the peripheral circuit 20 as shown in FIGS. 46 and 47, thereby forming a drain region 111 and a source region 112 in the semiconductor substrate 11.

Still further, an interlayer insulating film (not shown) made of, for example, a silicon oxide film is deposited all over the semiconductor substrate 11, which is followed by the formation of an interconnect layer, etc., such that the semiconductor memory according to the third embodiment is completed.

According to the semiconductor memory manufacturing method in the third embodiment of the present invention, it is possible to manufacture a semiconductor memory comprising a memory cell transistor wherein the gate insulating film 12 has the parallel gate insulating film 121 whose interface with the floating gate electrode 13 is parallel to the interface between the between-storage-layer-and-electrode insulating film 14c and the floating gate electrode 13 and the vertical gate insulating films 122 whose interface with the floating gate electrode 13 is vertical to the interface between the between-storage-layer-and-electrode insulating film 14c and the floating gate electrode 13.

As a result, the ratio of the facing areas S1/S2 of the memory cell transistor is higher than 1, such that the amount of the charge passing through the between-storage-layer-and-electrode insulating film 14c during the application of an electric field in the write and erase operations of the semiconductor memory can be greater than that in the gate insulating film 12.

Thus, it is possible to manufacture a semiconductor memory which transfers a charge between the control gate electrode 15 and the floating gate electrode 13 via the between-storage-layer-and-electrode insulating film 14c to perform the write and erase operations.

### Other Embodiments

While the present invention has been described above in connection with the first to third embodiments, it should not be understood that the discussion and the drawings which constitute part of this disclosure limit this invention. From this disclosure, various alternative embodiments, examples and operational techniques will be apparent to those skilled in the art.

In the first embodiment described above, the example has been shown wherein the between-storage-layer-and-electrode insulating film 14 has a structure in which a plurality of insulating films with different dielectric constants are stacked. However, a charge trap level can be formed in the between-storage-layer-and-electrode insulating film 14 to increase the electric conduction efficiency of the between-storage-layer-and-electrode insulating film 14.

This charge trap level requires that a level potential be higher than the Fermi level of the electrode, and a shallow energy level within 1 eV from the conduction band edge of the between-storage-layer-and-electrode insulating film 14 is desirable.

For example, nitrogen having unpaired electrons can be introduced to form the shallow charge trap level in the between-storage-layer-and-electrode insulating film 14.

Thus, it should be appreciated that the present invention includes various embodiments that are not described here. Therefore, the technical scope of the present invention is only determined by the inventive particular matters according to claims justified by the above description.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a plurality of memory cell transistors arranged in a memory cell array;
a select transistor which is disposed in the memory cell array and which selects the memory cell transistor; and
a peripheral circuit transistor provided in a peripheral circuit which controls the memory cell array,
the memory cell transistor including:
a gate insulating film provided on a semiconductor substrate;
a floating gate electrode as a charge storage layer provided on the gate insulating film;
a between-storage-layer-and-electrode insulating film which is provided on the floating gate electrode and through which the amount of passing charge is greater than that through the gate insulating film during the application of an electric field in write and erase operations of the semiconductor memory; and
a control gate electrode on the between-storage-layer-and-electrode insulating film.

2. The semiconductor memory device according to claim 1, wherein the thickness and material of the gate insulating film of the select transistor or the peripheral circuit transistor provided in the peripheral circuit are the same as those of the gate insulating film of the memory cell transistor.

3. The semiconductor memory device according to claim 1, wherein the between-storage-layer-and-electrode insulating film has a structure in which a plurality of insulating films with different dielectric constants are stacked.

4. The semiconductor memory device according to claim 3, wherein the between-storage-layer-and-electrode insulating film is constituted of a first insulating film on the floating gate electrode, a second insulating film on the first insulating film, and a third insulating film which is disposed on the second insulating film and which contacts the control gate electrode, the dielectric constants of the first and third insulating films being lower than the dielectric constant of the second insulating film.

5. The semiconductor memory device according to claim 4, wherein the second insulating film includes at least one of alumina, tantalum oxide, hafnium oxide and lanthanum oxide.

6. The semiconductor memory device according to claim 4, wherein the first and third insulating films include one of a silicon oxide film, a silicon oxynitride film and a silicon nitride film.

7. The semiconductor memory device according to claim 6, wherein the equivalent oxide thickness of the first and third insulating films is 0.8 nm or more and 3 nm or less.

8. The semiconductor memory device according to claim 1, wherein an area in which the control gate electrode faces the floating gate electrode is smaller than an area in which the floating gate electrode faces the semiconductor substrate.

9. The semiconductor memory device according to claim 1, wherein the dimension in a direction along the bit line direction of the control gate electrode is smaller than the dimension in a direction along the bit line direction of the floating gate electrode.

10. The semiconductor memory device according to claim 1, wherein the between-storage-layer-and-electrode insulating film is trapezoidal in a cross section along the bit line direction of the memory cell array.

11. The semiconductor memory device according to claim 10, wherein of the two parallel sides of the trapezoidal between-storage-layer-and-electrode insulating film, the long side contacts the floating gate electrode and the short side contacts the control gate electrode.

12. The semiconductor memory device according to claim 1, wherein a part of the semiconductor substrate where the gate insulating film is provided has a convex cross section in a direction perpendicular to the bit line direction, and the gate insulating film is constituted of a first gate insulating film disposed on the convex semiconductor substrate along a direction parallel to an interface between the floating gate electrode and the between-storage-layer-and-electrode insulating film, and a second gate insulating film disposed on the convex semiconductor substrate along a direction vertical to the interface between the floating gate electrode and the between-storage-layer-and-electrode insulating film.

13. The semiconductor memory device according to claim 1, wherein the gate insulating film is a silicon nitride film formed by a radical nitriding method.

14. A semiconductor memory device comprising:
a plurality of memory cell transistors arranged in a memory cell array;
a select transistor which is disposed in the memory cell array and which selects the memory cell transistor; and
a peripheral circuit transistor provided in a peripheral circuit which controls the memory cell array,
the memory cell transistor including:
a gate insulating film provided on a semiconductor substrate;
an insulating film as a charge storage layer provided on the gate insulating film;
a between-storage-layer-and-electrode insulating film which is provided on the insulating film as the charge storage layer and through which the amount of passing charge is greater than that through the gate insulating film during the application of an electric field in write and erase operations of the semiconductor memory; and
a control gate electrode on the between-storage-layer-and-electrode insulating film.

15. The semiconductor memory device according to claim 14, wherein the thickness and material of the gate insulating film of the select transistor or the peripheral circuit transistor are the same as those of the gate insulating film of the memory cell transistor.

16. The semiconductor memory device according to claim 14, wherein the between-storage-layer-and-electrode insulating film is a silicon oxide film or a silicon oxynitride film.

17. The semiconductor memory device according to claim 14, wherein the between-storage-layer-and-electrode insulating film has a structure in which a plurality of insulating films with different dielectric constants are stacked.

18. The semiconductor memory device according to claim 17, wherein the between-storage-layer-and-electrode insulating film is constituted of a first insulating film on the floating gate electrode, a second insulating film on the first insulating film, and a third insulating film which is disposed on the second insulating film and which contacts the control gate electrode, the dielectric constants of the first and third insulating films being lower than the dielectric constant of the second insulating film.

19. The semiconductor memory device according to claim 18, wherein the second insulating film includes at least one of alumina, tantalum oxide, hafnium oxide and lanthanum oxide.

20. The semiconductor memory device according to claim 18, wherein the first and third insulating films include one of a silicon oxide film, a silicon oxynitride film and a silicon nitride film.
